(19) United States
(12) Patent Application Publication
(10) Pub. No.: US 2025/0211193 A1
(43) Pub. Date: Jun. 26, 2025

(54) BULK ACOUSTIC WAVE DEVICE INCLUDING PIEZOELECTRIC LAYER WITH ENGINEERED REGION

(71) Applicant: Skyworks Global Pte. Ltd., Singapore (SG)

(72) Inventors: Yanbo He, Irvine, CA (US); Wan Wan, Irvine, CA (US); Kwang Jae Shin, Yongin-si (KR); Zongliang Cao, Irvine, CA (US)

(21) Appl. No.: 18/987,888

(22) Filed: Dec. 19, 2024

Related U.S. Application Data
(60) Provisional application No. 63/677,968, filed on Jul. 31, 2024.
(60) Provisional application No. 63/677,941, filed on Jul. 31, 2024.
(60) Provisional application No. 63/677,943, filed on Jul. 31, 2024.
(60) Provisional application No. 63/613,626, filed on Dec. 21, 2023.
(60) Provisional application No. 63/613,624, filed on Dec. 21, 2023.
(60) Provisional application No. 63/613,620, filed on Dec. 21, 2023.
(60) Provisional application No. 63/613,552, filed on Dec. 21, 2023.
(60) Provisional application No. 63/613,346, filed on Dec. 21, 2023.

(51) Int. Cl. H03H 9/02; H03H 3/02; H03H 9/17

(52) U.S. Cl. CPC H03H 9/02118; H03H 3/02; H03H 9/02031; H03H 9/173; H03H 9/176

(57) ABSTRACT

Aspects of this disclosure relate to a bulk acoustic wave device that includes an engineered piezoelectric layer. In certain embodiments, the bulk acoustic wave device includes a raised frame structure in a raised frame region. The raised frame structure can be positioned around a main acoustically active region of the bulk acoustic wave device. The bulk acoustic wave device can include a piezoelectric layer that is less piezoelectric in the raised frame region than in the main acoustically active region. Related filters, multiplexers, radio frequency modules, radio frequency systems, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/613,346, filed Dec. 21, 2023 and titled “BULK ACOUSTIC WAVE DEVICE INCLUDING PIEZOELECTRIC LAYER WITH ENGINEERED REGION,” and claims the benefit of priority of U.S. Provisional Application No. 63/613,552, filed Dec. 21, 2023 and titled “BULK ACOUSTIC WAVE DEVICE INCLUDING PIEZOELECTRIC LAYER HAVING DIFFERENT STRUCTURE IN DIFFERENT REGIONS,” and claims the benefit of priority of U.S. Provisional Application No. 63/613,620, filed Dec. 21, 2023 and titled “METHODS OF MANUFACTURING BULK ACOUSTIC WAVE DEVICE HAVING PIEZOELECTRIC LAYER WITH ENGINEERED REGION,” and claims the benefit of priority of U.S. Provisional Application No. 63/613,624, filed Dec. 21, 2023 and titled “METHODS OF FORMING PIEZOELECTRIC LAYER WITH DIFFERENT STRUCTURE IN DIFFERENT REGIONS OF BULK ACOUSTIC WAVE DEVICE,” and claims the benefit of priority of U.S. Provisional Application No. 63/613,626, filed Dec. 21, 2023 and titled “METHODS OF MANUFACTURING BULK ACOUSTIC WAVE DEVICE INCLUDING MODIFYING REGION OF PIEZOELECTRIC LAYER,” and claims the benefit of priority of U.S. Provisional Application No. 63/677,943, filed Jul. 31, 2024 and titled “TEMPERATURE COMPENSATED BULK ACOUSTIC WAVE DEVICE INCLUDING PIEZOELECTRIC LAYER WITH ENGINEERED REGION,” and claims the benefit of priority of U.S. Provisional Application No. 63/677,941, filed Jul. 31, 2024 and titled “FRAMELESS BULK ACOUSTIC WAVE DEVICE INCLUDING PIEZOELECTRIC LAYER WITH ENGINEERED REGION,” and claims the benefit of priority of U.S. Provisional Application No. 63/677,968, filed Jul. 31, 2024 and titled “BULK ACOUSTIC WAVE DEVICE INCLUDING SINGLE FRAME LAYER AND PIEZOELECTRIC LAYER WITH ENGINEERED REGION,” the disclosures of each of which are hereby incorporated by reference in their entireties and for all purposes.

### BACKGROUND

### Technical Field

The disclosed technology relates to acoustic wave devices. Embodiments of this disclosure relate to acoustic wave devices with a piezoelectric layer having an engineered region.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device having a main acoustically active region and a raised frame region. The bulk acoustic wave device includes a first electrode, a second electrode, a raised frame structure in the raised frame region, and a piezoelectric layer positioned between the first electrode and the second electrode in at least the main acoustically active region. The raised frame structure is positioned around the main acoustically active region. The piezoelectric layer is engineered in the raised frame region such that the piezoelectric layer has a greater magnitude effective piezoelectric coefficient in the main acoustically active region than in the raised frame region.

The piezoelectric layer can have deteriorated crystallinity in the raised frame region relative to in the main acoustically active region. The piezoelectric layer can be amorphous in the raised frame region.

The effective piezoelectric coefficient can an effective piezoelectric coupling coefficient (e₃₃). A magnitude of the effective piezoelectric coefficient is no more than 50% in the raised frame region of the magnitude of the effective piezoelectric coefficient in the main acoustically active region. A magnitude of the effective piezoelectric coefficient is no more than 20% in the raised frame region of the magnitude of the effective piezoelectric coefficient in the main acoustically active region.

The bulk acoustic wave can include a seed layer positioned between the first electrode and the piezoelectric layer in the raised frame region. The main acoustically active region can be free from the seed layer. The seed layer can include at least one of an oxide, a nitride, a carbide, or a boride material. The seed layer can include a metal base. The metal base can include aluminum.

The piezoelectric layer can include ions implanted therein in the raised frame region of the bulk acoustic wave device.

The piezoelectric layer can be engineered in an intermediate region of the bulk acoustic wave device that is between the raised frame region and the main acoustically active region.

The piezoelectric layer can be engineered in an outer region of the bulk acoustic wave device that is on an opposite side of the frame region than the main acoustically active region.

The bulk acoustic wave device can include a recessed frame structure in a recessed frame region. The recessed frame region can be between the main acoustically active region and the raised frame region. The piezoelectric layer can be engineered in at least part of the recessed frame region.

The raised frame region can include a first raised frame region and a second raised frame region. The raised frame structure can include an additional raised frame layer in the second raised frame region relative to in the first raised frame region.

The raised frame structure can include an oxide raised frame layer and a metal raised frame layer.

The bulk acoustic wave device can include an air cavity. The piezoelectric layer can be over the air cavity in the raised frame region and the main acoustically active region.

The piezoelectric layer can include aluminum nitride. The piezoelectric layer can include aluminum nitride doped with a dopant. The piezoelectric layer can include aluminum nitride doped with scandium. The piezoelectric layer can include aluminum nitride doped with a dopant selected from the group consisting of Y, Eu, Cr, Mg, Hf, Ca, Si, B, C, and Ge.

The raised frame structure can surround the main acoustically active region.

Another aspect of this disclosure is a bulk acoustic wave device having a main acoustically active region a peripheral region surrounding the main acoustically active region. The bulk acoustic wave device includes a first electrode, a second electrode, a frame structure at least partly in the peripheral region, and a piezoelectric layer positioned between the first electrode and the second electrode in at least the main acoustically active region. The piezoelectric layer is engineered in the peripheral region such that the piezoelectric layer has a greater magnitude effective piezoelectric coefficient in the main acoustically active region than in the peripheral region.

The frame structure can be fully within the peripheral region. The peripheral region can extend beyond the frame structure toward the main acoustically active region.

The frame structure can include a raised frame structure and a recessed frame structure.

The bulk acoustic wave deice can include a seed layer positioned between the first electrode and the piezoelectric layer in the peripheral region.

Another aspect of this disclosure is a bulk acoustic wave device having a main acoustically active region and a peripheral region. The bulk acoustic wave device includes a first electrode, a second electrode, a frame structure in at least part of the peripheral region, and a piezoelectric layer positioned between the first electrode and the second electrode in at least the main acoustically active region. The piezoelectric layer having a different structure in the peripheral region than in the main acoustically active region.

The frame structure can include a raised frame structure and a recessed frame structure. The frame structure can include only a recessed frame structure in some applications.

The frame structure can surround the main acoustically active region.

The peripheral region can include a first raised frame region and a second raised frame region. The frame structure can include an additional raised frame layer in the second raised frame region relative to in the first raised frame region.

The peripheral region can extend beyond the frame structure.

The piezoelectric layer has deteriorated crystallinity in the peripheral region relative to in the main acoustically active region. The piezoelectric layer can be amorphous in the peripheral region. The piezoelectric layer can have at least one of dislocations or stacking faults in the peripheral region. The piezoelectric layer can have a c-axis with a lack of a preferred orientation in the peripheral region. The piezoelectric layer can have a generally random grain orientation in the peripheral region.

The bulk acoustic wave device can include a seed layer positioned between the piezoelectric layer and the first electrode in the peripheral region. The seed layer may not positioned between the piezoelectric layer and the first electrode in the main acoustically active region.

The piezoelectric layer can have an implanted species therein in the peripheral region. The main acoustically active region can be free from the implanted species.

A c-axis of the piezoelectric layer in the peripheral region can be oriented at an angle in a range from 90° to 150° to relative to a c-axis of the piezoelectric layer in the main acoustically active region.

The piezoelectric layer can include aluminum nitride in the main acoustically active region and in the peripheral region.

The bulk acoustic wave device can include an air cavity. The piezoelectric layer can be over the air cavity in the peripheral region and the main acoustically active region.

The bulk acoustic wave device can include a solid acoustic mirror. The piezoelectric layer can be over the solid acoustic mirror in the peripheral region and the main acoustically active region.

Another aspect of this disclosure is a method of manufacturing a bulk acoustic wave device having a main acoustically active region and a peripheral region around the main acoustically active region. The method includes forming a piezoelectric layer over a first electrode such that the piezoelectric layer has a greater magnitude effective piezoelectric coefficient in the main acoustically active region than in the peripheral region. The method includes depositing a second electrode over the piezoelectric layer such that the piezoelectric layer is positioned between the first electrode and the second electrode in at least the main acoustically active region. The method also includes forming a frame structure at least partly in the peripheral region.

Forming the frame structure can be performed after the forming the piezoelectric layer.

The peripheral region can include a first raised frame region and a second raised frame region. Forming the frame structure can include forming an additional raised frame layer in the second raised frame region than in the first raised frame region.

The peripheral region can extend beyond the frame structure toward the main acoustically active region. The peripheral region can extend beyond the frame structure away from the main acoustically active region.

Forming the piezoelectric layer can include modifying the piezoelectric layer in the peripheral region such that the piezoelectric layer has the greater magnitude effective piezoelectric coefficient in the main acoustically active region than in the peripheral region. Modifying the piezoelectric layer can include ion implantation in the peripheral region.

Forming the piezoelectric layer can include forming the piezoelectric layer over a seed layer in the peripheral region. The seed layer can be over the first electrode. The main acoustically active region can be free from the seed layer over the first electrode during the forming the piezoelectric layer.

Forming the piezoelectric layer can include depositing the piezoelectric layer over a first material in the main acoustically active region and over a second material in the peripheral region, where the first material is different than the second material.

Forming the piezoelectric layer can include depositing the piezoelectric layer such that the piezoelectric layer has a different structure in the peripheral region than in the main acoustically active region.

The piezoelectric layer can include aluminum nitride in the main acoustically active region and in the peripheral region.

The main acoustically active region and the peripheral region can be over an air cavity. The main acoustically active region and the peripheral region can be over a solid acoustic mirror.

Another aspect of this disclosure is a method of manufacturing a bulk acoustic wave device having a main acoustically active region and a peripheral region surrounding the main acoustically active region. The method includes forming a piezoelectric layer over a first electrode such that the piezoelectric layer has a greater magnitude effective piezoelectric coefficient in the main acoustically active region than in the peripheral region, the piezoelectric layer being over an acoustic reflector in the main acoustically active region and in the peripheral region; depositing a second electrode over the piezoelectric layer such that the piezoelectric layer is positioned between the first electrode and the second electrode in the main acoustically active region; and forming a raised frame structure in the peripheral region.

The peripheral region can extend beyond the raised frame structure toward the main acoustically active region. The peripheral region can extend beyond the raised frame structure away from the main acoustically active region.

Forming the raised frame structure can be performed after the forming the piezoelectric layer.

Forming the raised frame structure can include forming a raised frame layer between the piezoelectric layer and the second electrode. Forming the raised frame structure can include forming a raised frame layer over the second electrode.

Another aspect of this disclosure is a method of manufacturing an acoustic wave filter. The method includes forming a bulk acoustic wave device with (i) a piezoelectric layer over a first electrode such that the piezoelectric layer has a greater magnitude effective piezoelectric coefficient in a main acoustically active region of the bulk acoustic wave device than in a peripheral region of the bulk acoustic wave device and (ii) a raised frame layer over an acoustic reflector, the raised frame layer being in the peripheral region of the bulk acoustic wave device; and electrically connecting the bulk acoustic wave device with another bulk acoustic wave device of the acoustic wave filter.

Another aspect of this disclosure is a method of manufacturing a bulk acoustic wave device having a main acoustically active region and a peripheral region around the main acoustically active region. The method includes forming a piezoelectric layer over a first material in the main acoustically active region and over a second material in the peripheral region such that the piezoelectric layer has a different structure in the peripheral region than in the main acoustically active region, the first material being different than the second material; depositing a second electrode over the piezoelectric layer such that the piezoelectric layer is positioned between a first electrode and the second electrode in the main acoustically active region; and forming a frame structure at least partly in the peripheral region.

A seed layer can include the second material. The second material can include at least on of an oxide, a nitride, a carbide, a carbon structure, or a boride. The second material can include silicon dioxide. The second material can include aluminum nitride.

The second material can have a thickness in a range from 5 nanometers to 150 nanometers.

The first electrode can include the first material.

Forming the frame structure in the peripheral region can include forming a raised frame layer over the piezoelectric layer.

The peripheral region can extend beyond the frame structure toward the main acoustically active region. The peripheral region can extend beyond the frame structure away from the main acoustically active region.

The frame structure can include a metal raised frame layer and an oxide raised frame layer.

The frame structure can be over an air cavity.

Another aspect of this disclosure is a method of manufacturing a bulk acoustic wave device having a main acoustically active region and a peripheral region surrounding the main acoustically active region. The method includes forming a piezoelectric layer over a first material in the main acoustically active region and over a second material in the peripheral region such that the piezoelectric layer has a different structure in the peripheral region than in the main acoustically active region, the first material being different than the second material; depositing a second electrode over the piezoelectric layer such that the piezoelectric layer is positioned between a first electrode and the second electrode in the main acoustically active region; and forming a raised frame structure in the peripheral region, the peripheral region extending beyond the raised frame structure.

The raised frame structure can include an oxide raised frame layer. The raised frame structure can include a metal raised frame layer. The raised frame structure can include an oxide raised frame layer and a metal raised frame layer.

The method can include forming a recessed frame structure in the peripheral region.

Another aspect of this disclosure is a method of manufacturing an acoustic wave filter. The method includes forming a piezoelectric layer over a first material in a main acoustically active region of a bulk acoustic wave device and over a second material in a peripheral region of the bulk acoustic wave device such that the piezoelectric layer has a different structure in the peripheral region than in the main acoustically active region, the first material being different than the second material; forming a raised frame structure in the peripheral region; and electrically connecting the bulk acoustic wave device with another bulk acoustic wave device of the acoustic wave filter.

The method can include forming an electrode over the piezoelectric layer.

The piezoelectric layer can be over an air cavity in the main acoustically active region and at least a portion of the peripheral region, and the raised frame structure can be over the air cavity.

Another aspect of this disclosure is a method of manufacturing a bulk acoustic wave device having a main acoustically active region and a peripheral region surrounding the main acoustically active region. The method includes providing a bulk acoustic wave device structure that includes a piezoelectric layer over a first electrode; modifying the piezoelectric layer in the peripheral region to reduce a magnitude of a piezoelectric coefficient of the piezoelectric layer in the peripheral region relative to in the main acoustically active region; and depositing a second electrode over the piezoelectric layer after the modifying.

Modifying the piezoelectric layer can deteriorate crystallinity in the peripheral region relative to in the main acoustically active region. Modifying the piezoelectric layer can make the piezoelectric layer amorphous in the peripheral region.

Modifying the piezoelectric layer can include performing ion implantation in the peripheral region. The ion implantation can introduce ions of chemically inert elements into the piezoelectric layer in the peripheral region.

The method can include forming a frame structure in the peripheral region. Forming the frame structure can be performed after modifying the piezoelectric layer. At least part of the forming the frame structure can be performed before modifying the piezoelectric layer. The peripheral region can extend beyond the frame structure toward the main acoustically active region. The peripheral region can extend beyond the frame structure away from the main acoustically active region. The frame structure can be over an air cavity.

Another aspect of this disclosure is a method of manufacturing a bulk acoustic wave device having a main acoustically active region and a peripheral region surrounding the main acoustically active region. The method includes modifying a piezoelectric layer in the peripheral region to reduce a magnitude of a piezoelectric coefficient of the piezoelectric layer in the peripheral region relative to in the main acoustically active region, the piezoelectric layer being over a first electrode in the main acoustically active region and the peripheral region; depositing a second electrode over the piezoelectric layer after the modifying; and forming a frame structure in the peripheral region, the peripheral region extending beyond the frame structure.

Another aspect of this disclosure is a method of manufacturing an acoustic wave filter. The method includes modifying a piezoelectric layer in a peripheral region of a bulk acoustic wave resonator to reduce a magnitude of a piezoelectric coefficient of the piezoelectric layer in the peripheral region relative to in a main acoustically active region of the bulk acoustic wave resonator, the piezoelectric layer being over a first electrode in the main acoustically active region and the peripheral region; forming additional features of the bulk acoustic wave resonator over the piezoelectric layer after the modifying; and electrically connecting the bulk acoustic wave resonator with a second bulk acoustic wave resonator of the acoustic wave filter.

The additional features can include a second electrode and at least a portion of a frame structure.

The piezoelectric layer can be over an air cavity in the main acoustically active region and at least a portion of the peripheral region.

The second bulk acoustic wave resonator can include an engineered piezoelectric layer.

The acoustic wave filter can be a band pass filter having a passband that corresponds to a fifth generation New Radio operating band.

The acoustic wave filter can be included in a multiplexer.

Another aspect of this disclosure is a bulk acoustic wave device having an acoustically active region and a peripheral region around the acoustically active region. The bulk acoustic wave device includes a first electrode, a second electrode, a temperature compensation layer, and a piezoelectric layer positioned between the first electrode and the second electrode in at least the acoustically active region. The piezoelectric layer has a greater magnitude effective piezoelectric coefficient in the acoustically active region than in the peripheral region.

The temperature compensation layer can be positioned between a surface of the first electrode and a surface of the second electrode. The temperature compensation layer can be positioned between a surface of the second electrode and the piezoelectric layer. The temperature compensation layer can be embedded in the second electrode.

The temperature compensation layer can have a positive temperature coefficient of frequency. The temperature compensation layer can include silicon dioxide.

The temperature compensation layer can be in the acoustically active region and the peripheral region.

The bulk acoustic wave device can include a frame structure positioned within the peripheral region. The frame structure can include a raised frame structure and a recessed frame structure. The peripheral region can include a first raised frame region and a second raised frame region, and the frame structure can include an additional raised frame layer in the second raised frame region relative to in the first raised frame region. The frame structure can include a metal raised frame layer. The frame structure can include an oxide raised frame layer.

The piezoelectric layer can have deteriorated crystallinity in the peripheral region relative to in the acoustically active region.

The effective piezoelectric coefficient is a piezoelectric coupling coefficient (e₃₃), and a magnitude of the effective piezoelectric coefficient in the peripheral region can be no more than 50% of the magnitude of the effective piezoelectric coefficient in the acoustically active region.

The bulk acoustic wave device can include a seed layer positioned between the first electrode and the piezoelectric layer in the peripheral region. The acoustically active region can be free from the seed layer between the first electrode and the seed layer.

The piezoelectric layer can include ions implanted therein in the peripheral region.

The bulk acoustic wave device can include an air cavity. The piezoelectric layer can be over the air cavity in the peripheral region and the acoustically active region.

The piezoelectric layer can include aluminum nitride doped with scandium.

Another aspect of this disclosure is a bulk acoustic wave device having an acoustically active region and a raised frame region. The bulk acoustic wave device includes a first electrode, a second electrode, a temperature compensation layer in the acoustically active region and the raised frame region, a raised frame structure in the raised frame region, and a piezoelectric layer positioned between the first electrode and the second electrode in at least the acoustically active region and the raised frame region. The temperature compensation layer has a positive temperature coefficient of frequency. The piezoelectric layer has a greater magnitude effective piezoelectric coefficient in the acoustically active region than in the raised frame region.

Another aspect of this disclosure is a bulk acoustic wave device having an acoustically active region and an engineered region. The bulk acoustic wave device includes a first electrode, a second electrode, an acoustic reflector, and a piezoelectric layer. The first electrode and the second electrode overlap each other on opposing sides of the piezoelectric layer and are over the acoustic reflector in the acoustically active region. The piezoelectric layer is engineered in the engineered region such that the piezoelectric layer has a greater magnitude effective piezoelectric coefficient in the acoustically active region than in the peripheral region. The bulk acoustic wave device has a resonant frequency of at least 2.5 gigahertz.

The resonant frequency can be in a range from 2.5 gigahertz to 7 gigahertz. The resonant frequency can be in a range from 3.3 gigahertz to 5 gigahertz.

The bulk acoustic wave device can be frameless over the piezoelectric layer. The bulk acoustic wave device can be frameless over the acoustic reflector. The bulk acoustic wave device can be frameless in an area that is both (a) outside of the acoustically active region and (b) over the acoustic reflector.

The engineered region can be a peripheral region that surrounds the acoustically active region.

The piezoelectric layer can have deteriorated crystallinity in the engineered region relative to in the acoustically active region. The piezoelectric layer can be amorphous in the engineered region.

The effective piezoelectric coefficient can be an effective piezoelectric coupling coefficient (e₃₃). A magnitude of the effective piezoelectric coefficient in the engineered region can be no more than 50% of the magnitude of the effective piezoelectric coefficient in the acoustically active region. A magnitude of the effective piezoelectric coefficient in the engineered region can be no more than 20% of the magnitude of the effective piezoelectric coefficient in the acoustically active region.

The bulk acoustic wave device can include a seed layer positioned between the first electrode and the piezoelectric layer in the engineered region. The acoustically active region can be free from the seed layer.

The piezoelectric layer can include ions implanted therein in the engineered region.

The acoustic reflector can be an air cavity. The acoustic reflector can be a cavity that is over a support substrate.

The piezoelectric layer can include aluminum nitride. The piezoelectric layer can be doped with scandium. The piezoelectric layer can be doped with a dopant selected from the group consisting of Y, Eu, Cr, Mg, Hf, Ca, Si, B, C, and Ge.

The bulk acoustic wave device can include a temperature compensation layer over the piezoelectric layer. The bulk acoustic wave device can include a temperature compensation layer positioned between the first electrode and the second electrode.

Another aspect of this disclosure is a bulk acoustic wave device having an acoustically active region and a peripheral region surrounding the acoustically active region. The bulk acoustic wave device includes a first electrode, a second electrode, an acoustic reflector, and a piezoelectric layer positioned over the acoustic reflector. The first electrode and the second electrode overlap each other on opposing sides of the piezoelectric layer in the acoustically active region. The piezoelectric layer is engineered in the peripheral region such that the piezoelectric layer has a greater magnitude effective piezoelectric coefficient in the acoustically active region than in the peripheral region.

Another aspect of this disclosure is a bulk acoustic wave device having an acoustically active region and a frame region. The bulk acoustic wave device includes a first electrode, a second electrode, a single layer raised frame structure in the frame region, and a piezoelectric layer positioned between the first electrode and the second electrode in at least the acoustically active region and the frame region. The piezoelectric layer is engineered in the frame region such that the piezoelectric layer has a greater magnitude effective piezoelectric coefficient in the acoustically active region than in the frame region.

The single layer raised frame structure can be an oxide layer. The single layer raised frame structure can be a silicon dioxide layer.

The single layer raised frame structure can be a dielectric layer.

The single layer raised frame structure can be a metal layer. The metal layer can be formed of a same material as the second electrode.

The single layer raised frame structure can include a same material as the piezoelectric layer in the frame region.

The single layer raised frame structure can be over the piezoelectric layer.

The frame structure can include a recessed frame structure in the frame region.

The piezoelectric layer can have deteriorated crystallinity in the frame region relative to in the acoustically active region. The piezoelectric layer can be amorphous in the frame region.

The effective piezoelectric coefficient can be a piezoelectric coupling coefficient (e33), and a magnitude of the effective piezoelectric coefficient in the frame region can be no more than 50% of the magnitude of the effective piezoelectric coefficient in the acoustically active region.

The bulk acoustic wave device can include a seed layer positioned between the first electrode and the piezoelectric layer in the frame region. The acoustically active region can be free from the seed layer.

The piezoelectric layer can include ions implanted therein in the peripheral region.

The bulk acoustic wave device can include a cavity. The piezoelectric layer can be over the cavity in the frame region and the acoustically active region.

The piezoelectric layer includes can be aluminum nitride. The piezoelectric layer can be doped with scandium.

The bulk acoustic wave device can include a temperature compensation layer positioned between the first electrode and the second electrode.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave device in accordance with any suitable principles and advantages disclosed herein.

The present disclosure relates to U.S. patent application Ser. No. ______ [Attorney Docket SKYWRKS.1502A2], titled “BULK ACOUSTIC WAVE DEVICE INCLUDING PIEZOELECTRIC LAYER HAVING DIFFERENT STRUCTURE IN DIFFERENT REGIONS,” filed on even date herewith, the entire disclosure of which is hereby incorporated by reference herein. The present disclosure relates to U.S. patent application Ser. No. ______ [Attorney Docket SKYWRKS.1502A3], titled “METHODS OF MANUFACTURING BULK ACOUSTIC WAVE DEVICE HAVING PIEZOELECTRIC LAYER WITH ENGINEERED REGION,” filed on even date herewith, the entire disclosure of which is hereby incorporated by reference herein. The present disclosure relates to U.S. patent application Ser. No. ______ [Attorney Docket SKYWRKS.1502A4], titled “METHODS OF FORMING PIEZOELECTRIC LAYER WITH DIFFERENT STRUCTURE IN DIFFERENT REGIONS OF BULK ACOUSTIC WAVE DEVICE,” filed on even date herewith, the entire disclosure of which is hereby incorporated by reference herein. The present disclosure relates to U.S. patent application Ser. No. ______ [Attorney Docket SKYWRKS.1502A5], titled “TEMPERATURE COMPENSATED BULK ACOUSTIC WAVE DEVICE INCLUDING PIEZOELECTRIC LAYER WITH ENGINEERED REGION,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a cross-sectional diagram of a bulk acoustic wave (BAW) device including a piezoelectric layer with an engineered region according to an embodiment.

FIG. 1B is an example plan view of the BAW device of FIG. 1A.

FIG. 2A is a cross-sectional diagram of a BAW device including a piezoelectric layer with an engineered region according to an embodiment. FIG. 2B illustrates a structure of a portion of the piezoelectric layer of the BAW device of FIG. 2A in the engineered region and in a main piezoelectric region. FIG. 2C illustrates structure of the piezoelectric layer of the BAW device of FIG. 2A for three different areas.

FIG. 3 is a cross-sectional diagram of a BAW device including an air cavity etched into a substrate and a piezoelectric layer with an engineered region according to an embodiment.

FIG. 4 is a cross-sectional diagram of a BAW device including a solid acoustic mirror and a piezoelectric layer with an engineered region according to an embodiment.

FIG. 5 is a cross-sectional diagram of a BAW device including a dual solid acoustic mirror and a piezoelectric layer with an engineered region according to an embodiment.

FIG. 6A is a cross-sectional diagram of a BAW device including a plurality of raised frame layers and a piezoelectric layer with an engineered region according to an embodiment. FIG. 6B is a zoomed in view of a metal top electrode connection area of the BAW device of FIG. 6A that includes the frame region. FIG. 6C is a zoomed in view of the frame region near a metal bottom electrode connection area of the BAW device of FIG. 6A.

FIG. 7 is a cross-sectional diagram of a BAW device including a suspended frame region and a piezoelectric layer with an engineered region according to an embodiment.

FIG. 8 is a cross-sectional diagram of a portion of a BAW device including a piezoelectric layer with an engineered region and a raised frame layer below the piezoelectric layer according to an embodiment.

FIG. 9 is a cross-sectional diagram of a portion of a BAW device including a piezoelectric layer with an engineered region and raised frame layers below the piezoelectric layer according to an embodiment.

FIG. 10 a cross-sectional diagram of a portion of a BAW device including a piezoelectric layer with an engineered region that extends beyond a frame region toward the main acoustically active region according to an embodiment.

FIG. 11 includes a graph of a frequency response of a BAW device with a piezoelectric layer with an engineered region compared to a frequency of a similar BAW device with a piezoelectric layer without the engineered region.

FIG. 12A illustrates a BAW device that includes a piezoelectric layer with an engineered region. FIG. 12B includes simulation results for a quality factor at parallel resonance (Qp) for various widths and thicknesses of a metal raised frame layer as a piezoelectric coefficient for the engineered region is increased. FIG. 12C includes simulation results for Qp for various widths and thicknesses of a metal raised frame layer as a quality factor Qbulk for the engineered region is increased.

FIG. 13A illustrates a portion of a BAW device that includes a piezoelectric layer with an engineered region. FIG. 13B is a graph that plots distributions of Qp of the BAW device of FIG. 13A for different piezoelectric coupling coefficient (e33) values for the engineered region. FIG. 13C is a graph that plots distributions of spur intensity of the BAW device of FIG. 13A for different e33 values of the engineered region.

FIG. 14 is a flow diagram of a method of manufacturing a BAW device with a piezoelectric layer with an engineered region according to an embodiment.

FIG. 15 is a flow diagram of a method of manufacturing a BAW device that involves forming a piezoelectric layer having different structures in different regions according to an embodiment.

FIGS. 16A, 16B, and 16C are cross-sectional diagrams of a BAW device structure at different points during the method of FIG. 15.

FIG. 17 is a flow diagram of a method of manufacturing a BAW device that involves modifying a piezoelectric layer in a peripheral region of the BAW device according to an embodiment.

FIGS. 18A, 18B, and 18C are cross-sectional diagrams of a BAW device structure at different points during the method of FIG. 17.

FIG. 19A illustrates a portion of a BAW device that includes a piezoelectric layer without an engineered region. FIGS. 19B, 19C, and 19D illustrate portions of respective BAW devices manufactured with methods according to embodiments.

FIG. 20A is a graph with frequency responses of the BAW devices of FIGS. 19A to 19D. FIG. 20B is a plot of Qp distributions for the BAW devices of FIGS. 19A to 19D. FIG. 20C is a plot of spur intensity distributions for the BAW devices of FIGS. 19A to 19D.

FIG. 21A is cross-sectional schematic diagram of a BAW device.

FIG. 21B is a graph of Qp for various width combinations of raised frame layers of the BAW device of FIG. 21A. FIG. 21C is a graph of spur intensity for various width combinations of raised frame layers of the BAW device of FIG. 21A.

FIG. 22A is cross-sectional schematic diagram of a BAW device according to an embodiment. FIG. 22B is a graph of Qp for various width combinations of raised frame layers of the BAW device of FIG. 22A. FIG. 22C is a graph of spur intensity for various width combinations of raised frame layers of the BAW device of FIG. 22A.

FIG. 23A is cross-sectional schematic diagram of a part of BAW device that includes an oxide raised frame layer and a piezoelectric layer with an engineered region according to an embodiment.

FIG. 23B is cross-sectional schematic diagram of a part of BAW device that includes a metal raised frame layer and a piezoelectric layer with an engineered region according to an embodiment.

FIG. 23C is cross-sectional schematic diagram of a part of BAW device that includes a piezoelectric raised frame layer and a piezoelectric layer with an engineered region according to an embodiment.

FIG. 24A is cross-sectional schematic diagram of a frameless BAW device that includes a piezoelectric layer with an engineered region according to an embodiment. FIG. 24B is a zoomed in view of part of the BAW device of FIG. 24A.

FIG. 25A is cross-sectional schematic diagram of a temperature compensated BAW device that includes a piezoelectric layer with an engineered region according to an embodiment. FIG. 25B is a zoomed in view of part of the temperature compensated BAW device of FIG. 25A.

FIG. 26A is a schematic diagram of a ladder filter that includes one or more BAW resonators according to an embodiment.

FIG. 26B is schematic diagram of a band pass filter.

FIGS. 27A, 27B, 27C, and 27D are schematic diagrams of multiplexers that include a filter with one or more BAW resonators according to an embodiment.

FIGS. 28, 29, and 30 are schematic block diagrams of modules that include a filter with one or more BAW resonators according to an embodiment.

FIG. 31 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Increasing the quality factor (Q) of a given bulk acoustic wave (BAW) resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices disclosed herein can achieve improved performance by engineering a region of a piezoelectric layer. Such engineering can degrade crystallinity of the engineered region of the piezoelectric layer.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of material that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A BAW device can include a first electrode, a second electrode, and a piezoelectric layer positioned between the first and second electrodes. A frame structure, such as a raised frame and/or a recessed frame, can be positioned around a main acoustically active region of the BAW device to reduce lateral energy leakage from the main acoustically active region. A region of the BAW device that includes the frame structure can be referred to as a frame region. A raised frame structure can create a resonance at a frequency that is below a resonant frequency of the main acoustically active region of the BAW device. This resonance can be below a main resonant frequency of the BAW device. A resonance associated with the raised frame structure can be referred to as a raised frame mode. The raised frame mode can be undesirable in certain applications.

This disclosure provides technical solutions that can suppress and/or eliminate raised frame modes. At the same time, technical solutions disclosed herein can maintain a desired electromechanical coupling coefficient (kt²) and significantly increase a quality factor (Q) of a BAW device. BAW devices disclosed herein include an engineered region of a piezoelectric layer that can suppress a frame mode of a frame structure. These BAW devices can be referred to as having an engineered passive frame. BAW devices disclosed herein can achieve significant performance improvements over other BAW devices. Filters that include BAW devices disclosed herein can provide improved performance in a variety of applications, such as but not limited to fifth generation (5G) New Radio (NR) applications. BAW devices disclosed herein can improve performance in applications where a plurality of filters are connected together with each other.

Aspects of this disclosure relate to a BAW device that includes a piezoelectric layer with an engineered region. The piezoelectric layer can have a lower magnitude effective piezoelectric coefficient in the engineered region than in a region in the main acoustically active region of the BAW device. The piezoelectric coefficient can be a piezoelectric coupling coefficient (e₃₃), for example. The engineered region of piezoelectric layer can be in a peripheral region of the BAW device that surrounds the main acoustically active region of the BAW device. The main acoustically active region and at least part of the peripheral region can both be over an acoustic reflector, such as an air cavity or a solid acoustic mirror, of the BAW device. The BAW device can include a frame structure in the peripheral region. The frame structure can include one or more raised frame structures and/or one or more recessed frame structures. The peripheral region can extend beyond the frame structure toward the main acoustically active region and/or away from the main acoustically active region. For example, the peripheral region can extend beyond a raised frame structure toward the main acoustically active region and/or away from the main acoustically active region. By reducing and/or eliminating the piezoelectric properties of the piezoelectric layer in the peripheral region of the BAW device, there can be little or no resonance associated with the frame structure. The piezoelectric layer can be engineered in a continuous region or in discrete regions in accordance with any suitable principles or advantages disclosed herein.

Aspects of this disclosure relate to manufacturing BAW devices that include a piezoelectric layer with an engineered region. In some embodiments, a uniform piezoelectric layer can be deposited and then the engineered region of the piezoelectric layer can be modified to be less piezoelectric than the main piezoelectric region of the piezoelectric layer. For example, ions can be implanted to modify the structure and properties of the piezoelectric layer in the engineered region by ion implantation. In such embodiments, the piezoelectric layer can be engineered from a side opposite the lower electrode of a BAW device. In some embodiments, the piezoelectric layer can be deposited over different materials in a peripheral region of the BAW device and in the main acoustically active region of the BAW device such that the piezoelectric layer is less piezoelectric in the peripheral region of the BAW device. For example, a seed layer can be provided over a lower electrode of the BAW device in the peripheral region and lower electrode can be free from the seed layer in the main acoustically active region. Depositing the piezoelectric layer over the seed layer in the peripheral region can cause the piezoelectric layer to have a different structure and different properties in the peripheral region than in the main acoustically active region. In these embodiments, the piezoelectric layer can be engineered from a lower electrode side.

The engineered region of a piezoelectric layer in BAW devices disclosed herein and/or manufactured according to methods disclosed herein can have a piezoelectric coupling coefficient (e₃₃) with a magnitude than is in a range from 0% to less than 100% of the piezoelectric coupling coefficient of the piezoelectric layer in the main acoustically active region. In certain embodiments, the e₃₃ has a magnitude in the engineered region that is 50% or less of a magnitude in the main acoustically active region. In some embodiments, the e₃₃ has a magnitude in the engineered region that is 20% or less of a magnitude in the main acoustically active region. In some embodiments, the e₃₃ has a magnitude in the engineered region that is 10% or less of a magnitude in the main acoustically active region. The reduced magnitude of the piezoelectric coupling coefficient in the engineered region of the piezoelectric layer can increase Q of the BAW device and/or attenuate one or more spurs, such a spur associated with one or more frame modes.

BAW devices disclosed herein can significantly attenuate one more spurious modes and increase Q, while maintaining an electromechanical coupling coefficient (kt²) at a relatively stable level. This can effectively decouple Q, kt² and strength of spurious modes in BAW devices.

BAW Devices with Piezoelectric Layer Having Engineered Region

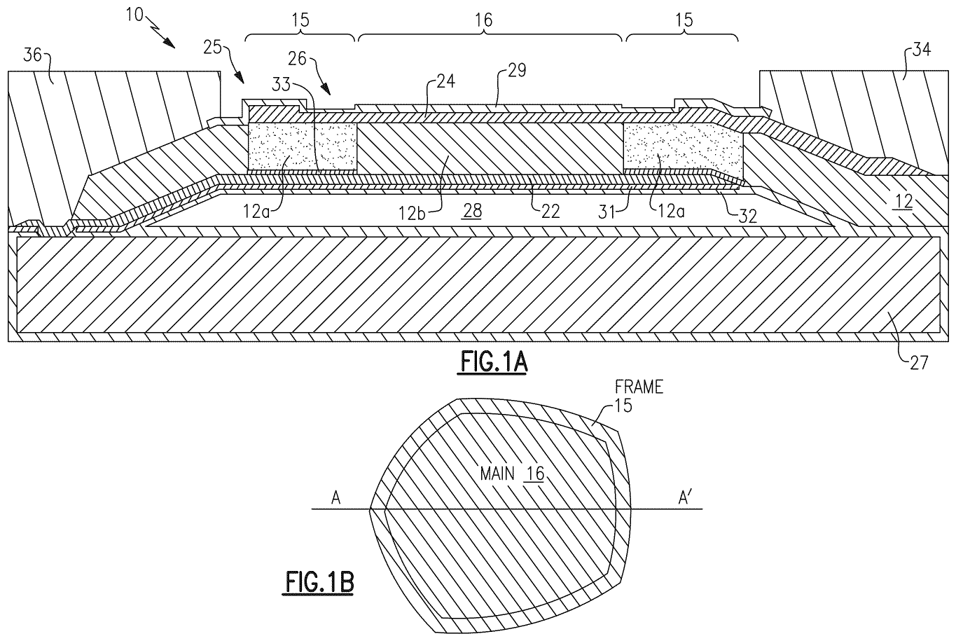

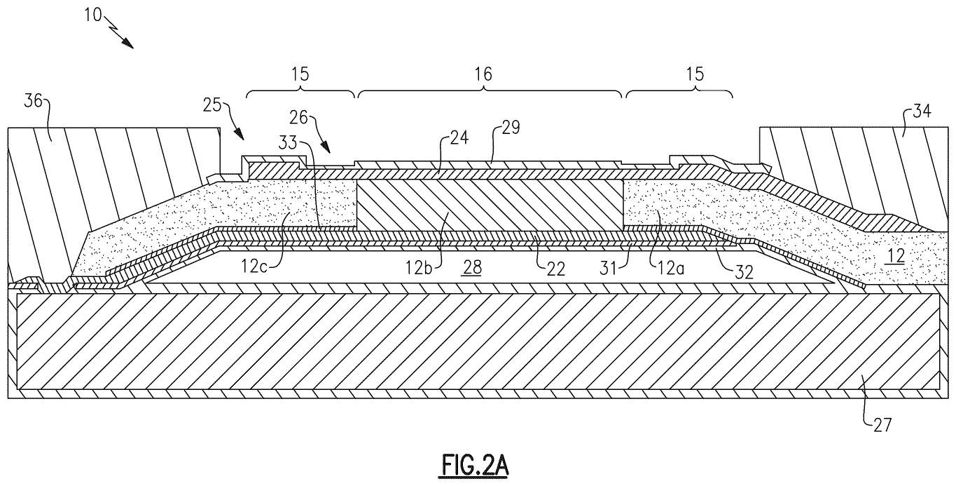

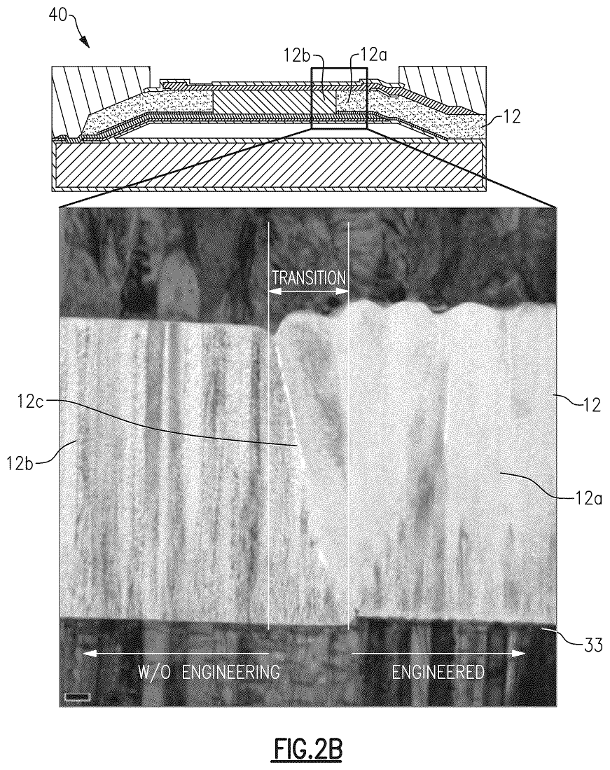

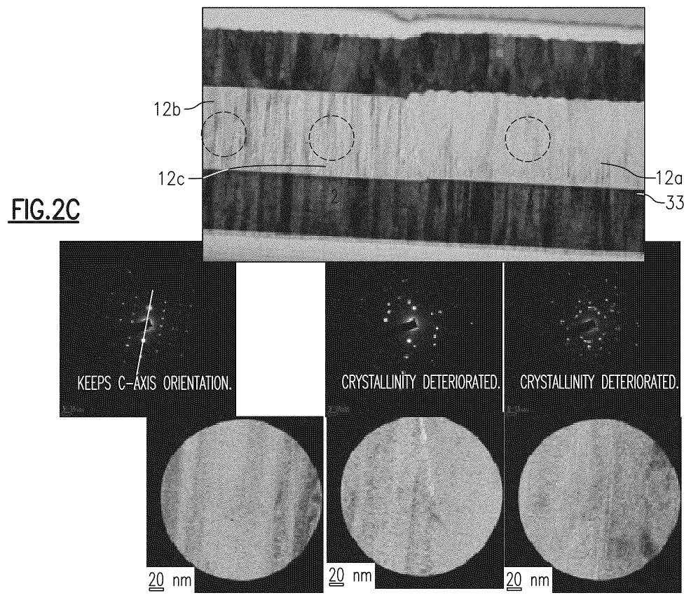

A BAW device can include a piezoelectric layer with an engineered region in a peripheral region of the BAW device. Examples of such a BAW device will be discussed with reference to FIGS. 1A to 2C. Any suitable principles and advantages of these BAW devices can be implemented together with each other and/or with any suitable principles and advantages of other embodiments disclosed herein. BAW devices disclosed herein can be BAW resonators.

FIG. 1A is a cross-sectional diagram of a BAW device 10 including a piezoelectric layer 12 with an engineered region 12a according to an embodiment. In the BAW device 10, the engineered region 12a of piezoelectric layer 12 is in a frame region 15 of the BAW device 10. In the BAW device 15, a peripheral region includes the frame region 15. The engineered region 12a can be referred to as a passive piezoelectric region. The engineered region 12a can be referred to as a less piezoelectric region. The engineered region 12a can be referred to as a damaged region. In some applications, the engineered region 12a can be referred to as a non-piezoelectric region. The piezoelectric layer 12 also includes a main piezoelectric region 12b in a main acoustically active region 16 of the BAW device 10. The piezoelectric layer 12 can have a significantly higher bulk piezoelectric effect in the main piezoelectric region 12b than in the engineered region 12a. The main piezoelectric region 12b can be referred to as an active piezoelectric region of the piezoelectric layer 12. The main piezoelectric region 12b can be referred to as an acoustically active region of the piezoelectric layer 12. The main piezoelectric region 12b can be referred to as a regular region of the piezoelectric layer 12. The frame region 15 surrounds the main acoustically active region 16 in plan view in the BAW device 10.

As illustrated, the BAW device 10 includes the piezoelectric layer 12, a first electrode 22, a second electrode 24, a raised frame structure 25, a recessed raised frame structure 26, a support substrate 27, an acoustic reflector such as an air cavity 28, and a passivation layer 29. The BAW device 10 also includes a seed layer 31 positioned between the first electrode 22 and passivation layer 32 and a seed layer 33 in the frame region 15 positioned between the first electrode 22 and the engineered region 12a of the piezoelectric layer 12.

The piezoelectric layer 12 has a different structure in the engineered region 12a than in the main piezoelectric region 12b. The piezoelectric layer 12 can have deteriorated crystallinity in the engineered region 12a relative to in the main piezoelectric region 12b. The piezoelectric layer 12 can be amorphous in the engineered region 12a. The engineered region 12a of the piezoelectric layer 12 can have a lack of a preferred orientation of the c-axis and/or a random grain orientation. In some instances, the c-axis of the piezoelectric layer 12 in an engineered region 12a can be oriented at an angle in a range from 90° to 150° (e.g., about 120°) to relative to a c-axis of the piezoelectric layer 12 in the main piezoelectric region 12b. The engineered region 12a of the piezoelectric layer 12 can have a defect laden structure containing features, such as dislocations and/or stacking faults, which decrease the piezoelectric response of the piezoelectric layer 12 in the engineered region 12a. In some instances, the engineered region 12a of the piezoelectric layer 12 can have nearly equal volumes of c-axis oriented regions of opposite polarity. The structure of the piezoelectric layer 12 in the engineered region 12a can cause the BAW device 10 to exhibit no bulk piezoelectric effect or a weak bulk piezoelectric effect in the frame region 15 of the BAW device 10.

In the BAW device 10, the piezoelectric layer 12 has different properties in the frame region 15 than in the main acoustically active region 16. The piezoelectric layer 12 can be less piezoelectric in the engineered region 12a than in other regions. The piezoelectric layer 12 is engineered in the frame region 15 such that the piezoelectric layer 12 has a greater magnitude effective piezoelectric coefficient in the main acoustically active region 16 than in the frame region 15.

The effective piezoelectric coefficient of the engineered region 12a can be an aggregate piezoelectric coefficient for the entire engineered region 12a. The aggregate magnitude of the piezoelectric polarization vectors in the engineered region 12a should be less than the magnitude in the main piezoelectric region 12b. For example, the engineered region 12a of the piezoelectric layer 12 can have an effective piezoelectric coefficient magnitude that is less than 50% of the effective piezoelectric coefficient magnitude of the main piezoelectric region 12b of the piezoelectric layer 12. The lower magnitude effective piezoelectric coefficient in the engineered region 12a can be a result of the non-aligned nature of piezoelectric material crystal orientations within the engineered region 12a causing a lower aggregate magnitude of the piezoelectric polarization vectors than in the main piezoelectric region 12b.

The effective piezoelectric coefficient can be an effective piezoelectric coupling coefficient (e₃₃), for example. In certain applications, the magnitude of the effective piezoelectric coupling coefficient of the piezoelectric layer 12 in the frame region 15 can be no more than 50% of the magnitude of the effective piezoelectric coupling coefficient of the piezoelectric layer 12 in the main acoustically active region 16. In some applications, the magnitude of the effective piezoelectric coupling coefficient of the piezoelectric layer 12 in the frame region 15 can be no more than 20% of the magnitude of the effective piezoelectric coupling coefficient of the piezoelectric layer 12 in the main acoustically active region 16. In some applications, the magnitude of the effective piezoelectric coupling coefficient of the piezoelectric layer 12 in the frame region 15 can be zero or close to zero. The piezoelectric layer 12 also has a lower electrotechnical coupling coefficient (kt²) in the frame region 15 relative to the main acoustically active region 16.

Although the engineered region 12a of the piezoelectric may exhibit little or no bulk piezoelectric effect, the engineered region 12a is considered part of the piezoelectric layer 12 in this disclosure. The engineered region 12a and the main piezoelectric region 12b can both generally be formed of a same material as a layer of the BAW device. For example, the engineered region 12a and the main piezoelectric region 12b can both be aluminum nitride layers in certain applications. In some such instances, the engineered region 12a and the main piezoelectric region 12b can both be aluminum nitride layers doped with a same dopant, such as scandium.

In the BAW device 10, the seed layer 33 can cause the piezoelectric layer 12 to be engineered in the engineered region 12a. The seed layer 33 can be a material that has relatively poor crystallinity or is crystalline with a relatively poor lattice match to the piezoelectric film applied over the seed layer 33. Accordingly, the piezoelectric layer 12 in the engineered region 12a over the seed layer 33 can have poor bulk piezoelectric properties. The seed layer 33 can be directly over the first electrode 22.

The seed layer 33 can be a layer formed by any suitable process, such as but not limited to atomic layer deposition (ALD), physical vapor deposition (PVD), pulsed laser deposition (PLD), or chemical vapor deposition (CVD). The seed layer 33 can include, but is not limited to, an oxide, a nitride, a carbide, a carbon structure (e.g., graphene or diamond), a boride, or any suitable combination thereof. In certain applications, the seed layer 33 can include one or more of aluminum oxide, silicon, silicon carbide, doped aluminum nitride, undoped aluminum nitride, aluminum, fused silica, boron nitride, diamond, silicon oxycarbide glass, silicon oxynitride glass, boron carbide, graphene, beryllium oxide, gallium nitride, indium nitride, silicon nitride, scandium nitride, or the like. In certain applications, the seed layer 33 can be an aluminum nitride layer.

The seed layer 33 can be a relatively thin layer. Accordingly, such a seed layer 33 can be referred to as a thin seed layer. The seed layer 33 can have a thickness that is in a single digit nanometer range. The seed layer 33 can have a thickness that is in a range from 5 nanometers to 150 nanometers. The seed layer 33 can have a thickness that is in a range from 10 nanometers to 100 nanometers. In certain applications, the seed layer 33 can have a thickness of 150 nanometers or less. In some of these applications, the seed layer 33 can have a thickness of 25 nanometers or less.

In certain applications, the piezoelectric layer 12 can be modified in the engineered region 12 after being deposited. For example, the piezoelectric layer 12 can be modified by ion implantation. The engineered region 12a of the piezoelectric layer BAW device 10 can be engineered by a combination of deposition over the seed layer 33 and modification after deposition in some applications.

BAW device 10 includes frame structure including raised frame structure 25 and recessed frame structure 26. The engineered region 12a of the piezoelectric layer 12 overlaps with the raised frame structure 25 and the recessed frame structure 26 in the BAW device 10. The reduced or lack of bulk piezoelectric effect in the engineered region 12a can suppress and/or eliminate a raised frame mode associated with the raised frame structure and a recessed frame mode associated with the recessed frame structure 26 in the BAW device 10.

The piezoelectric layer 12 can be formed of any suitable piezoelectric material such as, but not limited to, aluminum nitride (AlN), zinc oxide (ZnO), or lead zirconium titanate (PZT). In certain applications, the piezoelectric layer 12 can include AlN. The piezoelectric layer 12 can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), calcium (Ca), boron (B), carbon (C), europium (Eu), or the like. In certain applications, the piezoelectric layer 12 can be AlN based layer doped with Sc. Doping the piezoelectric layer 12 can adjust the resonant frequency. Doping the piezoelectric layer 12 can increase the electromechanical coupling coefficient (kt²) of the BAW device 10. Doping to increase the kt² can be advantageous at higher frequencies where kt² can be degraded.

In certain applications, two or more piezoelectric layers in accordance with any suitable principles and advantages disclosed herein can be stacked with each other between electrodes of a BAW device. The stacked piezoelectric layers can have c-axes oriented in opposite directions in the main acoustically active region and excite an overtone mode as a main mode of a BAW resonator. One or more of the stacked piezoelectric layers can include an engineered region in accordance with any suitable principles and advantages disclosed herein.

The piezoelectric layer 12 is positioned between the first electrode 22 and the second electrode 24 in the main acoustically active region 16 and the frame region 15 in the BAW device 10. The first electrode 22 can be referred to as a lower electrode. The first electrode 22 can have a relatively high acoustic impedance. The first electrode 22 can include molybdenum (Mo), tungsten (W), ruthenium (Ru), chromium (Cr), iridium (Ir), platinum (Pt), Ir/Pt, or any suitable alloy and/or combination thereof. Similarly, the second electrode 22 can have a relatively high acoustic impedance. The second electrode 24 can include Mo, W, Ru, Cr, Ir, Pt, Ir/Pt, or any suitable alloy and/or combination thereof. The second electrode 24 can be formed of the same material as the first electrode 22 in certain applications. The second electrode 24 can be referred to as an upper electrode. The thickness of the first electrode 22 can be approximately the same as the thickness of the second electrode 24 in the main acoustically active region 16 of the BAW device 10.

The seed layer 31 is positioned between the first electrode 22 and the passivation layer 32. The seed layer 31 can be any suitable seed layer for depositing the first electrode 22 thereon. The passivation layer 32 can be positioned between the air cavity 28 and the first electrode 22. The passivation layer 32 can be referred to as a lower passivation layer. The passivation layer 32 can be a silicon dioxide layer or any other suitable passivation layer, such as a layer including aluminum oxide, silicon carbide, aluminum nitride, silicon nitride, silicon oxynitride, or the like.

The piezoelectric layer 12 and the electrodes 22 and 24 are positioned over a support substrate 27. The support substrate 27 can be a semiconductor substrate. The support substrate 27 can be a silicon substrate. The support substrate 27 can be any other suitable support substrate, such as but not limited to a quartz substrate, a silicon carbide substrate, a sapphire substrate, a glass substrate, or any suitable ceramic substrate (e.g., spinel, alumina, etc.).

As illustrated in FIG. 1A, the air cavity 28 is located above the support substrate 27. The air cavity 28 is an example of an acoustic reflector. The air cavity 28 is positioned between the support substrate 27 and the first electrode 22. In the BAW device 10, the entire engineered region 12a of the piezoelectric layer 12 is positioned over the air cavity 28. In some applications, an air cavity can be etched into a support substrate, for example as shown in FIG. 3. In certain applications, a solid acoustic mirror with alternating high acoustic impedance and low acoustic impedance layers can be included in place of an air cavity, for example as shown in FIGS. 4 and 5. A BAW device with an air cavity can be referred to as a film bulk acoustic wave resonator (FBAR). A BAW device with a solid acoustic mirror can be referred to as a BAW solidly mounted resonator (SMR).

The passivation layer 29 is positioned over the second electrode 24. The passivation layer 29 can be referred to as an upper passivation layer. The passivation layer 29 can be a silicon dioxide layer or any other suitable passivation layer, such as a layer including aluminum oxide, silicon carbide, aluminum nitride, silicon nitride, silicon oxynitride, or the like. In certain applications, the passivation layer 29 and the passivation layer 32 are both the same material. The passivation layer 29 can have different thicknesses in different regions of the BAW device 10. Part of the passivation layer 29 where the passivation layer 29 is thinner can form at least part of the recessed frame structure 26.

The main acoustically active region 16 of the BAW device 10 corresponds to the portion of the piezoelectric layer 12 surrounded by the engineered region 12a of the piezoelectric layer 12. In the main acoustically active region 16, the piezoelectric layer 12 overlaps with the air cavity 28 and is between the first electrode 22 and the second electrode 24. Voltage applied on opposing sides of the piezoelectric layer 12 in the main acoustically active region 16 can generate a bulk acoustic wave in the piezoelectric layer 12. The main acoustically active region 16 can provide a main mode of the BAW device 10. The main mode can be the mode with the highest coupling or highest kt². The main acoustically active region 16 can be the central part of the active region that is free from the engineered region 12a of the piezoelectric layer 12. The main acoustically active region 16 can also be free from frame structures, such as the recessed frame structure 26 and the raised frame structure 25. The frame region 15 includes the raised frame structure 25 and the recessed frame structure 26.

While the BAW device 10 includes the raised frame structure 25 and recessed frame structure 26, other frame structures can alternatively or additionally be implemented. For example, a raised frame structure with multiple layers including a layer between an electrode of a BAW device and a piezoelectric layer can be implemented. As another example, a floating raised frame structure can be implemented. As one more example, a raised frame structure can be implemented without a recessed frame structure. As one more example, a recessed frame structure can be implemented without a raised frame structure. Any of these frame structures can vertically overlap with an engineered region of a piezoelectric layer over an acoustic reflector in accordance with any suitable principles and advantages disclosed herein.

One or more conductive layers 34 and 36 can connect an electrode of the BAW device 10 to one or more other BAW devices, one or more integrated passive devices, one or more other circuit elements, one or more signal ports, the like, or any suitable combination thereof.

FIG. 1B is an example plan view of the BAW device 10 of FIG. 1A. The cross-sectional view of FIG. 1A can be along the line from A to A′ in FIG. 1B. In FIG. 1B, the frame region 15 and the main acoustically active region 16 are shown. As illustrated, the main acoustically active region 16 can correspond to the majority of the area of the BAW device 10. The frame region 15 surrounds the main acoustically active region 16 in plan view. The frame region 15 includes the recessed frame structure 26 and the raised frame structure 25 of the BAW device 10 of FIG. 1A.

FIG. 1B illustrates the BAW device 10 with a pentagon shape with curved sides in plan view. Any other BAW devices disclosed herein can have a pentagon shaped with curved sides in plan view. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides.

FIG. 2A is a cross-sectional diagram of a BAW device 40 including a piezoelectric layer 12 with an engineered region 12a according to an embodiment. The BAW device 40 is similar to the BAW device 10 of FIG. 1A, except that the engineered region 12a is a larger portion of the piezoelectric layer 12 in the BAW device 40. The engineered region 12a of the piezoelectric layer 12 extends beyond the frame region 15 away from the main acoustically active region 16 of the BAW device 40. As illustrated, the engineered region 12a extends beyond the frame region 15 away from the main acoustically active region 16 on opposing sides of the BAW device 40. In some other embodiments, an engineered region can extend beyond a frame region on one side of a BAW device. The engineered region 12a in the BAW device 40A extends beyond where the first electrode 22 overlaps with the second electrode 24.

The BAW device 40 includes a seed layer 33 between the engineered region 12a of the piezoelectric layer 12 and the lower electrode 22. The seed layer 33 in the BAW device 40 is included over a larger portion of the first electrode 22 than the seed layer 33 in the BAW device 10 of FIG. 1A.

FIG. 2B illustrates a structure of a portion of the piezoelectric layer 12 of the BAW device 40 in the engineered region 12a and in the main piezoelectric region 12b. FIG. 2B illustrates that the engineered region 12a over the seed layer 33 has a different structure than the main piezoelectric region 12b of the piezoelectric layer. FIG. 2B also illustrates a transition region 12C of the piezoelectric layer 12.

FIG. 2C illustrates structure of the piezoelectric layer 12 of the BAW device 40 for three different areas. In a first area in the main piezoelectric region 12b, the piezoelectric layer 12 has a desired c-axis orientation for generating a bulk acoustic wave. There is no seed layer 33 under the main piezoelectric region 12b. The c-axis can be orientated generally orthogonal to a surface of the first electrode 22 in the main piezoelectric region 12b. Where the piezoelectric layer 12 is engineered as shown in FIG. 2C, the piezoelectric layer 12 has a c-axis that is not orthogonal to the surface of the first electrode 12. Instead, where the piezoelectric layer 12 is engineered, the c-axis can be oriented diagonally and/or in a random direction. In a second area in the transition region 12C, the piezoelectric layer 12 has deteriorated crystallinity relative to in the main piezoelectric region 12b. In a third area in the engineered region 12a, the piezoelectric layer 12 has deteriorated crystallinity. The seed layer 33 is positioned below the engineered region 12a of the piezoelectric layer 12. The seed layer 33 can have a thickness that is in a nanometer range, for example. The seed layer 33 can have a thickness that is less than 25 nanometers, for example. The seed layer 33 can include aluminum or aluminum nitride. The seed layer 33 can be formed by atomic layer deposition (ALD), physical vapor deposition (PVD) (e.g., sputtering, evaporation, etc.), pulsed laser deposition (PLD), plasma enhanced chemical vapor deposition (PECVD), metal organic chemical vapor deposition (MOCVD), molecular beam epitaxy (MBE), or any other suitable deposition technique.

BAW Devices with Various Acoustic Reflectors and Engineered Piezoelectric Layer

The piezoelectric layers with an engineered region disclosed herein can be implemented in a variety of different BAW devices. Such BAW devices can include any suitable acoustic reflector. Example BAW devices with different acoustic reflectors than the BAW device 10 of FIG. 1A are shown in FIGS. 3 to 5. Any suitable principles and advantages of these BAW devices can be implemented together with each other and/or with any suitable principles and advantages of other embodiments disclosed herein.

FIG. 3 is a cross-sectional diagram of a BAW device 50 including an air cavity 52 etched into a substrate 27 and a piezoelectric layer 12 with an engineered region 12a according to an embodiment. As illustrated in FIG. 3, the engineered region 12a can extend beyond an acoustic reflector, such as the air cavity 52. A portion of the engineered region 12a vertically overlaps with a raised frame structure over the acoustic reflector in the BAW device 50. Any suitable principles and advantages disclosed herein with reference to BAW devices with an air cavity over a substrate can be applied to BAW devices with an air cavity etched into a substrate.

FIG. 4 is a cross-sectional diagram of a BAW device 55 including a solid acoustic mirror 57 and a piezoelectric layer 12 with an engineered region 12a according to an embodiment. The BAW device 55 is a BAW solidly mounted resonator (SMR). The BAW device 55 includes a solid acoustic mirror 57 in place of an air cavity as an acoustic reflector. The solid acoustic mirror 57 is an acoustic Bragg reflector. The solid acoustic mirror 57 includes alternating low acoustic impedance layers and high acoustic impedance layers. As one example, the solid acoustic mirror 57 can include alternating silicon dioxide layers as low acoustic impedance layers and tungsten layers as high acoustic impedance layers. Any suitable principles and advantages disclosed herein with reference to FBARs be applied to BAW SMRs.

FIG. 5 is a cross-sectional diagram of a BAW device 58 including a dual solid acoustic mirror and a piezoelectric layer 12 with an engineered region 12a according to an embodiment. The BAW device 58 is like the BAW device 55 of FIG. 4, except that the BAW device 58 includes a second solid acoustic mirror 59 positioned over the second electrode 24. In the BAW device 58, the piezoelectric layer 12 and electrodes 22 and 24 are positioned between the solid acoustic mirror 56 and the second solid acoustic mirror 59 in the main acoustically active region. The frame region of the BAW device 58 can be free from the second solid acoustic mirror 59. The frame region of the BAW device 58 overlaps with the acoustic mirror 57 in the BAW device 58. A raised frame structure of the BAW device 58 overlaps with the acoustic mirror 57 in the BAW device 58.

BAW Devices with Various Frame Structures and Engineered Piezoelectric Layer

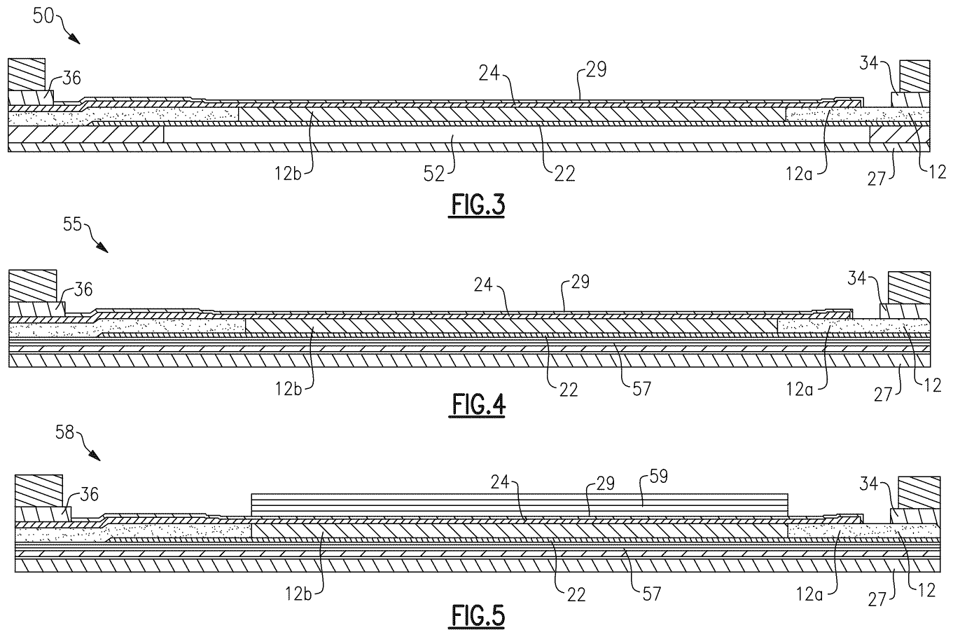

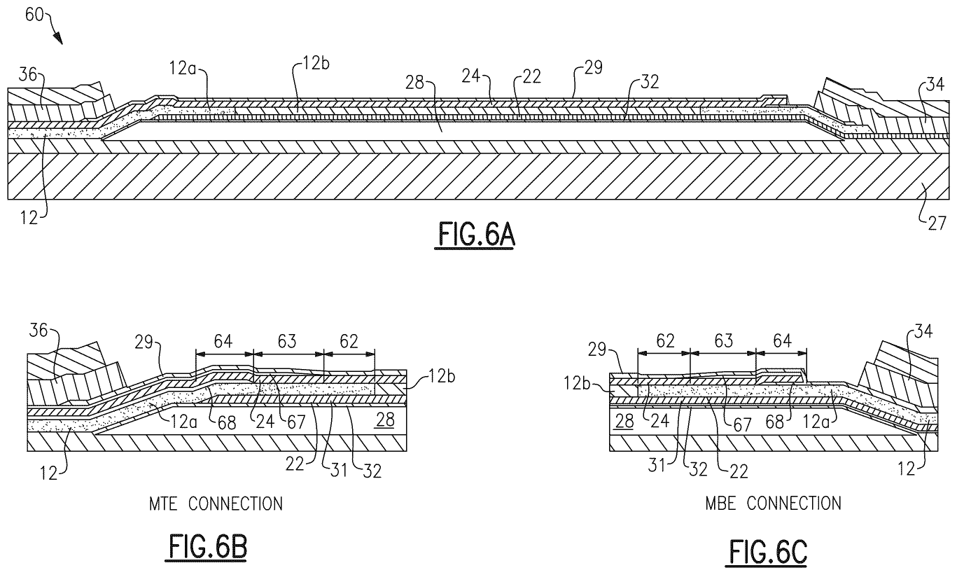

BAW devices that include a piezoelectric layer with an engineered region can include a variety of different frame structures. Such frame structures can reduce lateral energy leakage from a main acoustically active region of a BAW device. Example BAW devices with various frame structures are shown in FIGS. 6A to 9. Any suitable principles and advantages of these BAW devices can be implemented together with each other and/or with any suitable principles and advantages of other embodiments disclosed herein.

A BAW device in accordance with any suitable principles and advantages disclosed herein can include a frame structure with any suitable number of raised frame layers. A raised frame structure can include a metal raised frame layer and/or a dielectric raised frame layer. A BAW device in accordance with any suitable principles and advantages disclosed herein can include a frame structure with any suitable number of recessed frame structures. A recessed frame structure can include a thinner portion of one or more of a dielectric layer, a metal layer, or a piezoelectric layer in a recessed frame region. A BAW device in accordance with any suitable principles and advantages disclosed herein can include a frame structure without any recessed frame structures. A BAW device in accordance with any suitable principles and advantages disclosed herein can include a frame structure without any raised frame structures.

FIG. 6A is a cross-sectional diagram of a BAW device 60 including a plurality of raised frame layers and a piezoelectric layer 12 with an engineered region 12a according to an embodiment. The BAW device 60 also includes an air cavity 28 over a substrate 27. The BAW device 60 is similar to the BAW device 40 of FIG. 2A, except that and the BAW device 60 includes a different frame structure and the engineered region 12a in the BAW device 60 extends further in a direction away from the main acoustically active region in the BAW device 60. The engineered region 12a of the piezoelectric layer 12 extends beyond the air cavity 28 in the BAW device 60.

FIG. 6B is a zoomed in view of a metal top electrode connection area of the BAW device 60 that includes the frame region. The second electrode 24 is the top electrode in the BAW device 60. In FIG. 6B, the second electrode 24 connects to conductive layer 36. FIG. 6C is a zoomed in view of the frame region near a bottom electrode connection area of the BAW device 60. The first electrode 22 is the bottom electrode in the BAW device 60. The first electrode 22 connects to conductive layer 34 beyond the zoomed in portion shown in FIG. 6C.

Referring to FIGS. 6B and 6C, the frame region of the BAW device 60 includes a recessed frame region 62, a first raised frame region 63, and a second raised frame region 64. Raised frame regions can include one or more raised frame layers. A raised frame layer can be a metal layer, an oxide layer, or any other suitable layer. The BAW device 60 includes an additional raised frame layer in the second raised frame region 64 relative to in the first raised frame region 63. A recessed frame structure can include one or more layers that are thinner in a recessed frame region than in the main acoustically active region.

In the recessed frame region 62 of the BAW device 60, the passivation layer 29 is thinner than in the main acoustically active region of the BAW device 60. Such a recessed frame structure can be formed, for example, by etching the passivation layer 29 in the recessed frame region 62. In some other applications, such a recessed frame structure can be formed by forming additional passivation material of the passivation layer 29 in regions of the BAW device 60 outside of the recessed frame region 62. The passivation layer 29 can include, but is not limited to, one or more of silicon dioxide (SiO₂), silicon nitride (Si₃N₄), aluminum oxide (Al₂O₃), aluminum nitride (AlN), a carbide, a boride, hafnium dioxide (HfO₂), or tantalum pentoxide (Ta₂O₅).

Although the BAW device 60 includes a thinner passivation layer 29 in the recessed frame region 62 than in the main acoustically active region, a recessed frame structure of a BAW device can alternatively or additionally include one or more of a thinner second electrode, a thinner piezoelectric layer, a thinner first electrode, or a thinner seed layer in the recessed frame region than in the main acoustically active region.

The BAW device 60 includes a metal raised frame layer 67 in the first raised frame region 63. As illustrated, the metal raised frame layer 67 is positioned between the second electrode 24 and the passivation layer 29. With a metal raised frame layer 67, the first raised frame region 63 can be referred to as a metal raised frame region. A metal raised frame layer can alternatively or additionally be positioned in any other suitable position in the material stack of a BAW device. In certain applications, the metal raised frame layer 67 includes a same material as the second electrode 24. The metal raised frame layer 67 can include any suitable metal.

The BAW device 60 includes the metal raised frame layer 67 and an oxide raised frame layer 68 in the second raised frame region 64. With an oxide raised frame layer 68, the second raised frame region 64 can be referred to as an oxide raised frame region. As illustrated, the oxide raised frame layer 68 is positioned between the piezoelectric layer 12 and the second electrode 24. An oxide raised frame layer can alternatively or additionally be positioned in any other suitable position in the material stack of a BAW device. The oxide raised frame layer 68 can be a silicon dioxide layer, for example. The oxide raised frame layer 68 can be any other suitable oxide. Any other suitable passivation layer or any other suitable dielectric layer can be implemented in place of the oxide raised frame layer.

Raised frame structures of a BAW device can have the same or different dimensions on a metal top electrode connection side as on a metal bottom electrode side. Raised frame structures of a BAW device can have the same or different shapes on a metal top electrode connection side as on a metal bottom electrode side. The materials of the frame structures on the metal top electrode connection side can be the same or different as on the metal bottom electrode side in a BAW device.

FIG. 7 is a cross-sectional diagram of a BAW device 70 including a piezoelectric layer 12 with an engineered region 12a according to an embodiment. The BAW device 70 includes a suspended frame region 72. The BAW device 70 also includes a recessed frame region 62, a first raised frame region 63, and a second raised frame region 64. The engineered region 12a of piezoelectric layer 12 can suppress and/or eliminate spurious modes from each of the frame regions of the BAW device 70.

A raised frame layer can be included in any suitable position in a material stack of a BAW device. BAW devices can include raised frame layers on opposing sides of a piezoelectric layer. BAW devices can include a raised frame layer embedded in a piezoelectric layer. BAW devices can include a plurality of raised frame layers on a same side of the piezoelectric layer.

In some applications, the frame structure on a metal top electrode connection side of a BAW device can be different than the frame structure on a metal bottom electrode side of the BAW device. For example, raised frame structures can have different geometries on the metal top electrode connection side and the metal bottom electrode side of a BAW device. As another example, a raised frame layer (e.g., a dielectric layer) can be included on a metal top electrode connection side of a BAW device and not included on a metal bottom electrode side of the BAW device.

Some BAW devices can include a raised frame layer on a side of the piezoelectric layer that is opposite the acoustic reflector and another raised frame layer either embedded in the piezoelectric layer or on the opposite side of the piezoelectric layer than the raised frame layer.

FIG. 8 is a cross-sectional diagram of a portion of a BAW device 80 including a piezoelectric layer 12 with an engineered region 12a according to an embodiment. The BAW device 80 includes a first raised frame layer 82 and a second raised frame layer 84.

The first raised frame layer 82 is over the piezoelectric layer 12 on a side opposite to the acoustic reflector (not illustrated in FIG. 8) and support substrate (not illustrated in FIG. 8) of the BAW device 80. The first raised frame layer 82 is positioned between the second electrode 24 and the passivation layer 29. The first raised frame layer 82 can be a metal layer. For example, the first raised frame layer 82 can be a metal layer that is the same material as the second electrode 24. The first raised frame layer 82 can be a dielectric layer. For instance, the first raised frame layer 82 can be a dielectric layer that is the same material as the passivation layer 29.

The second raised frame layer 84 is positioned below material of the piezoelectric layer 12 in the BAW device 80. The second raised frame layer 84 can be embedded in the piezoelectric layer 12. The piezoelectric layer 12 can be engineered above and/or below the second raised frame layer 84. For example, as illustrated in FIG. 8, the piezoelectric layer 12 includes an engineered region 12a over the second raised frame layer 84. Although the second raised frame layer 84 is show as being deposited over material of the piezoelectric layer 12, a second raised frame layer can alternatively or additionally be deposited over the first electrode 22 and below the entire piezoelectric layer 12 in some other applications. The second raised frame layer 84 can be a metal layer or a dielectric layer. For example, the second raised frame layer 84 can be a silicon dioxide layer. A thickness of the second raised frame layer 84 can be in a range from greater than zero to less than a maximum thickness of the piezoelectric layer 12. A thickness of the piezoelectric layer 12 below the second raised frame structure can be in a range from zero to less than a maximum thickness of the piezoelectric layer 12.

The BAW device 80 includes two raised frame regions in which a raised frame structure is located and the piezoelectric layer 12 is positioned between the electrodes 22 and 24. In a first raised frame region of the BAW device 80, only the second raised frame layer 84 is present. The first raised frame layer 82 and the second raised frame layer 84 overlap in a second raised frame region of the BAW device 80. The first raised frame layer 82 and the second raised frame layer 84 can have different widths. For example, in the BAW device 80, the second raised frame layer 84 has a greater width than the first raised frame layer 82.

As illustrated in FIG. 8, the BAW device 80 does not include a recessed frame structure. In some other applications, the raised frame structure of the BAW device 80 can be implemented in a BAW device that also includes a recessed frame structure.

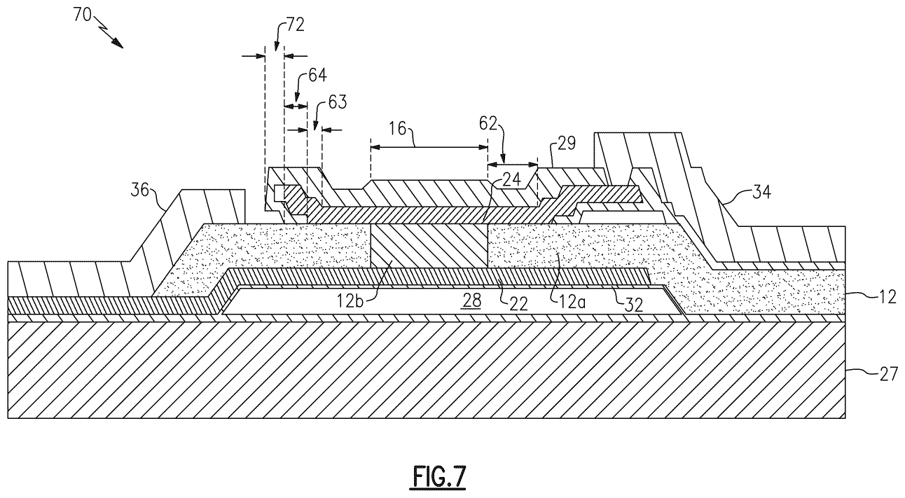

Some BAW devices can include a plurality of raised frame layers on a side of the piezoelectric layer that faces the acoustic reflector. An example of such a BAW device will be discussed with reference to FIG. 9.

FIG. 9 is a cross-sectional diagram of a portion of a BAW device 90 including a piezoelectric layer 12 with an engineered region 12a according to an embodiment. The BAW device 90 includes a first raised frame layer 82 and a second raised frame layer 84 that are both positioned between the piezoelectric layer 12 and the first electrode 22. In the BAW device 90, the first raised frame layer 82 and the second raised frame layer 84 are on a side of the piezoelectric layer 12 that faces the acoustic reflector (not illustrated in FIG. 9). In the BAW device 90, the second raised frame layer 84 can function as a seed layer that causes the piezoelectric layer 12 to be engineered in the engineered region 12a. The first raised frame layer 82 and the second raised frame layer 84 can be in physical contact each other in the BAW device 90. In some other applications, there can be an intervening layer or an air gap between the first raised frame layer 82 and the second raised frame layer 84 in a BAW device similar to the BAW device 90. The first raised frame layer 82 and the second raised frame layer 84 can have equal widths. In some other applications, the first raised frame layer 82 and the second raised frame layer 84 can have different widths. As illustrated in FIG. 9, the BAW device 90 includes a recessed frame structure 26. In some other applications, the raised frame structure of the BAW device 90 can be implemented in a BAW device that does not include a recessed frame structure.

### Position of Engineered Region of Piezoelectric Layer in BAW Devices

To achieve a higher quality factor at parallel resonance (Qp), a piezoelectric layer can include an engineered region in at least a frame region. Such a frame region can include one or more raised frame regions and/or one or more recessed frame regions. Lower Qp may be achieved when the engineered region of the piezoelectric layer does not span the frame region relative to when the engineered region of the piezoelectric layer spans the frame region. In certain embodiments, the engineered region of the piezoelectric layer can at least span the frame region that includes all raised frame region(s). In certain embodiments, the engineered region of the piezoelectric layer can at least span the frame region that includes all raised frame region(s) and/or recessed frame region(s) of the BAW device.

In some applications, an edge of the engineered region can align with an edge of the frame region on a side adjacent to the main acoustically active region. The engineered region of the piezoelectric layer can extend into an intermediate region that is between the frame region and the main acoustically active region. When the engineered region of the piezoelectric layer extends into such an intermediate region, Q can be improved, kt² can be relatively stable, frame modes can be suppressed, and the same or a similar level of lateral mode intensity can be present between fd and fs.

FIG. 10 a cross-sectional diagram of a portion of a BAW device 100 including a piezoelectric layer 12 with an engineered region 12a that extends into an intermediate region 102 of the BAW device 100 according to an embodiment. The intermediate region 102 is between the frame region 15 and the main acoustically active region 16 in the BAW device 100. The engineered region 12a can extend beyond the frame region 15 toward the main acoustically active region 16 to ensure that the engineered region 12a spans the entire frame region 15 even with offsets and/or other variations in manufacturing. The BAW device 100 can achieve desirable Q and suppress and/or eliminate frame modes.

In some embodiments such as the BAW device 10 of FIG. 1A, an edge of the engineered region can align with an edge of the frame region on a side opposite to the main acoustically active region. Alternatively, in some other embodiments such as the BAW device 40 of FIG. 2A, the engineered region of the piezoelectric layer can extend into an outer region that is on an opposite side of a frame region than the main acoustically active region.

Performance of BAWs Device with Engineered Piezoelectric Layer

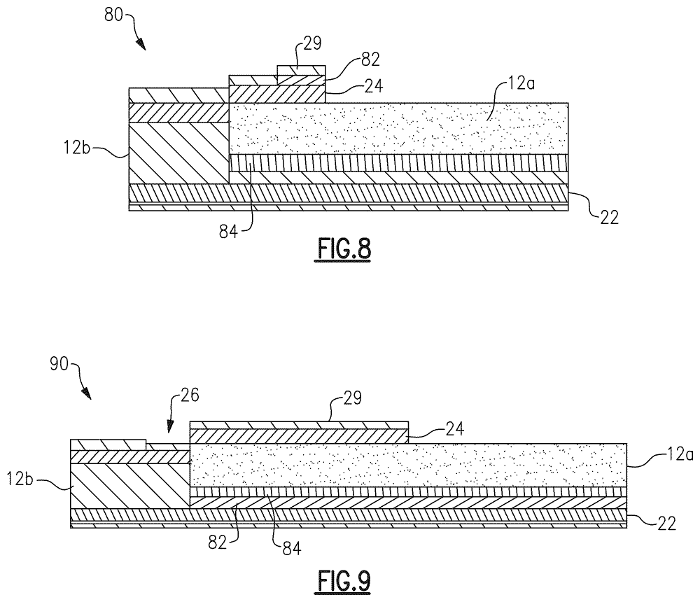

FIG. 11 includes a graph of a frequency response of a BAW device with a piezoelectric layer with an engineered region compared to a frequency of a similar BAW device with a piezoelectric layer without the engineered region. FIG. 11 indicates significant improvement in the frequency response of the BAW device with the engineered region 12a. The improvement in the frequency response is significant below the resonant frequency where intensity of spurious modes is significantly reduced by the engineered region. Without the engineered region, the similar BAW device has degraded performance below the resonant frequency that can be due to frame modes of the similar BAW device. The BAW device with the piezoelectric layer with the engineered region has a significantly increased Qp compared to the similar BAW device.

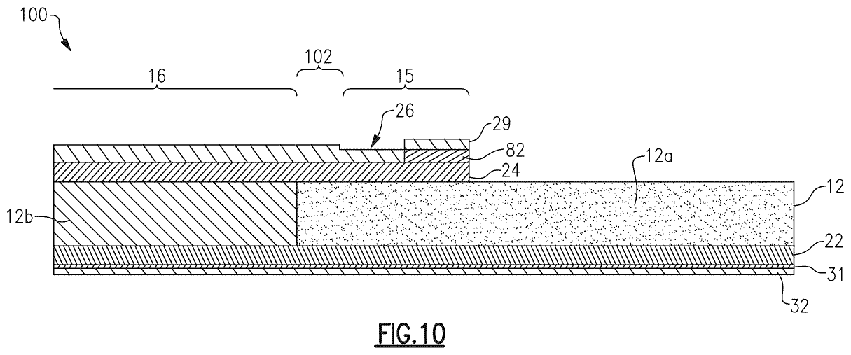

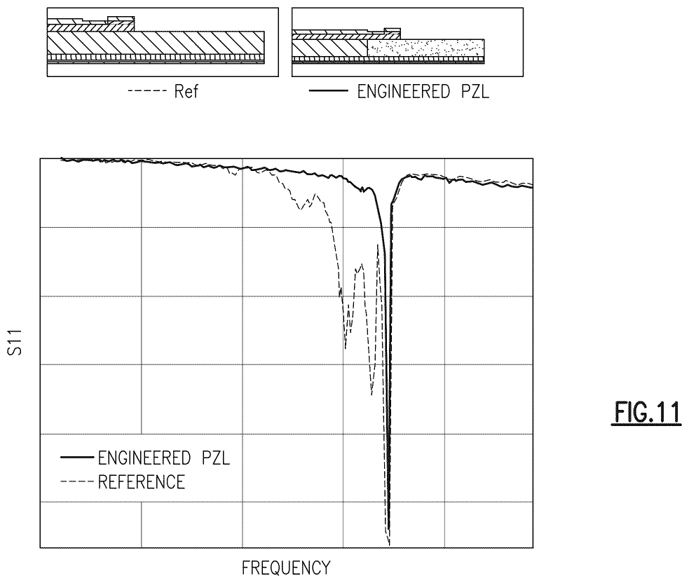

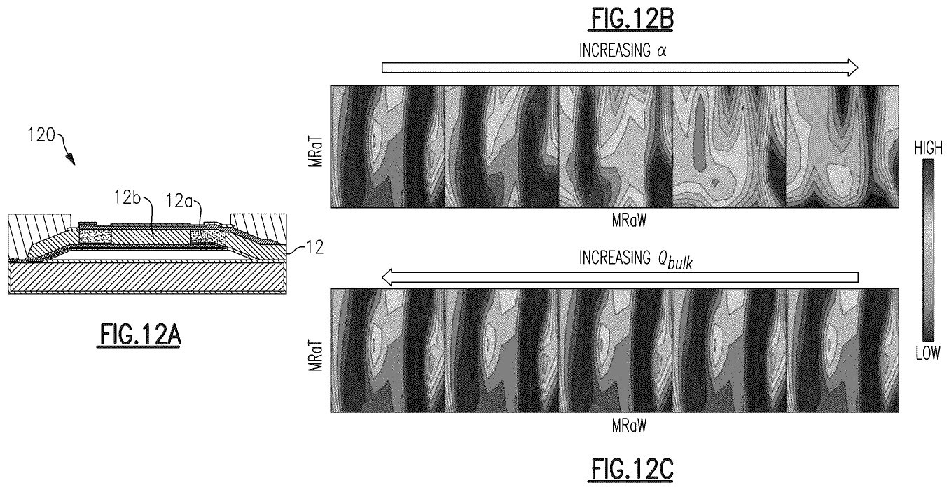

FIG. 12A illustrates a BAW device 120 that includes a piezoelectric layer 12 with an engineered region 12a. FIG. 12B includes simulation results for Qp for various widths and thicknesses MRaT of a metal raised frame layer as a piezoelectric coefficient α for the engineered region 12a is increased. FIG. 12B indicates that reducing the piezoelectric coefficient α for the engineered region 12a can increase the overall Qp of the BAW device 120. FIG. 12C includes simulation results for Qp for various widths and thicknesses MRaT of a metal raised frame layer as a quality factor Qbulk for the engineered region is increased. FIG. 12C bulk loss associated with the engineered region 12a represented by Qbulk may not impact the overall Qp of the BAW device 120.

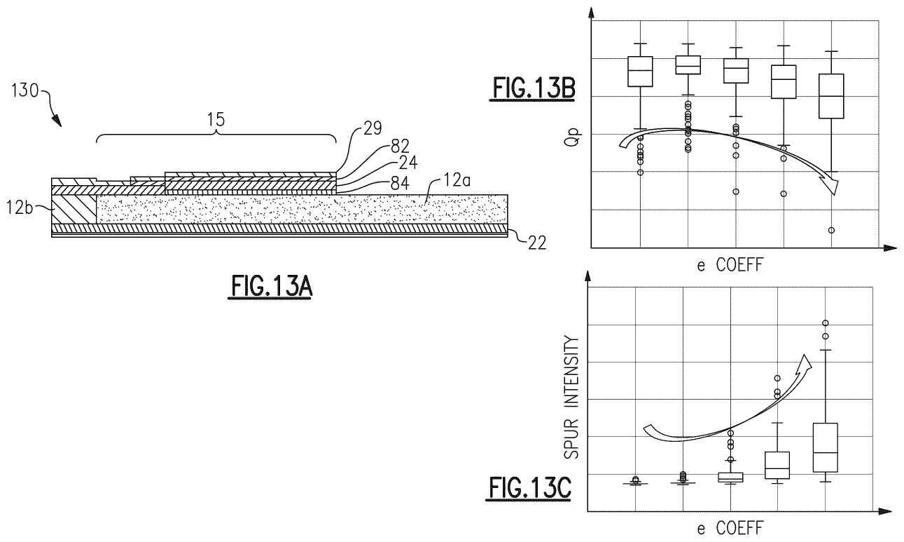

FIG. 13A illustrates a portion of a BAW device 130 that includes a piezoelectric layer 12 with an engineered region 12a. The frame region 15 of the BAW device 130 includes a recessed frame region and two raised frame regions. FIG. 13B is a graph that plots distributions of Qp of the BAW device 130 for different piezoelectric coupling coefficient (e₃₃) values for the engineered region of the BAW device 130. FIG. 13B indicates that Qp of the BAW device 130 is generally higher for lower e₃₃ values for the engineered region 12a. FIG. 13C is a graph that plots distributions of spur intensity of the BAW device 130 for different e₃₃ values of the engineered region 12a of the BAW device 130. This graph indicates that spur intensity increases as e₃₃ values increase. The impact of reducing e₃₃ for the engineered region 12a can begin to saturate at around 50% of the value of e₃₃ for the main acoustically active region of the BAW device 130.

Methods of Manufacturing BAW Device with Engineered Piezoelectric Layer

BAW devices that include a piezoelectric layer with an engineered region in accordance with any suitable principles and advantages disclosed herein can be manufactured using a variety of methods. The engineered region can be formed by forming the piezoelectric layer over different materials in different regions of a BAW device such that the piezoelectric layer has a different structure in the engineered region than in the main acoustically active region. In some other applications, the engineered region can be formed by modifying a generally uniform piezoelectric layer. According to some applications, engineered region of a piezoelectric layer can be formed by forming the piezoelectric layer over different materials in different regions and also subsequently modifying the piezoelectric layer in the engineered region. A BAW device can be manufactured in accordance with any suitable principles and advantages of any of the methods disclosed herein.

FIG. 14 is a flow diagram of a method 140 of manufacturing a BAW device according to an embodiment. The method 140 can be performed to form any suitable BAW device with an engineered piezoelectric layer in accordance with any suitable principles and advantages disclosed herein.

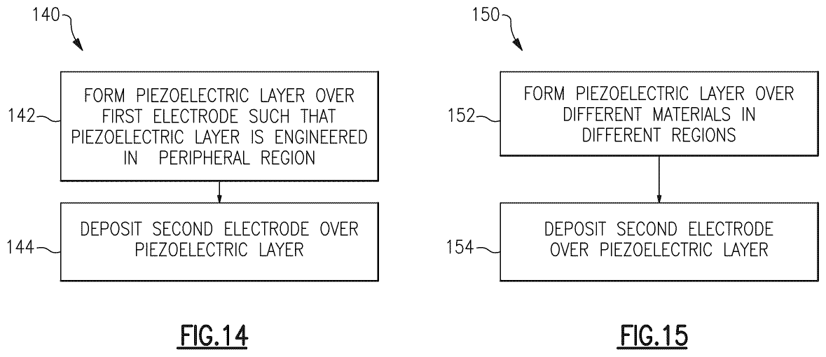

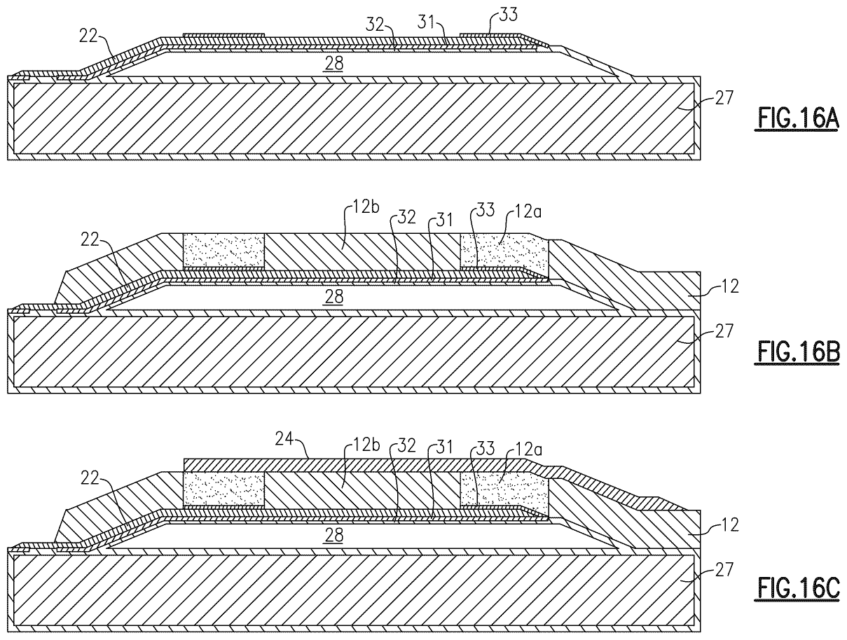

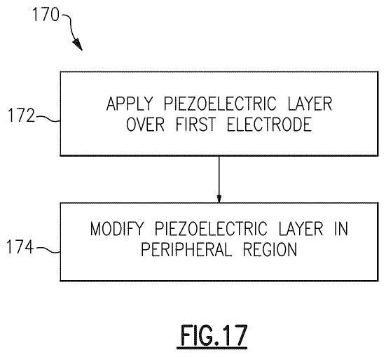

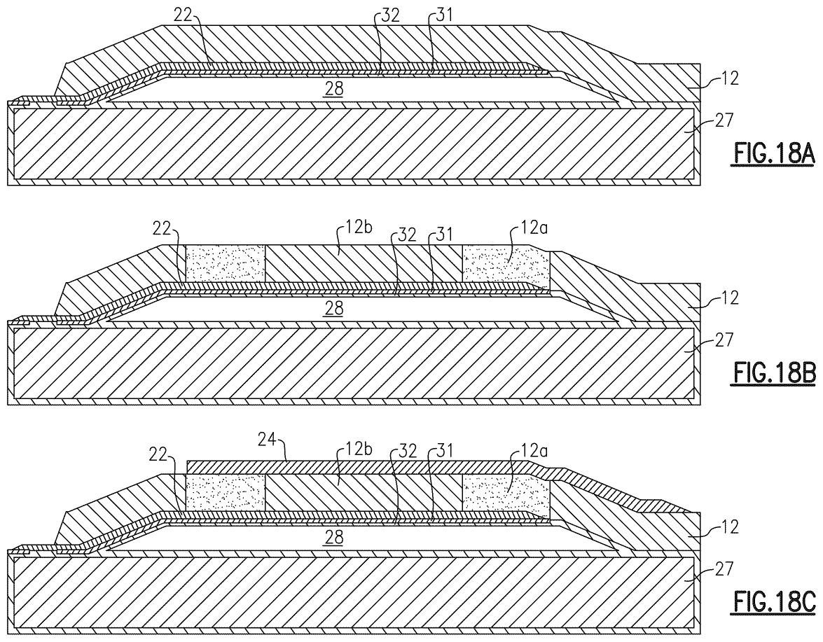

The method 140 includes forming a piezoelectric layer over a first electrode such that the piezoelectric layer is engineered in peripheral region at block 142. This can involve forming the piezoelectric layer such that the piezoelectric layer has a greater magnitude effective piezoelectric coefficient in the main acoustically active region than in the peripheral region. The peripheral region can include the frame region. In some instances, the peripheral region can include an outer region on an opposite side of the frame region than the main acoustically active region. Alternatively or additionally, the peripheral region can include an intermediate region between the frame region than the main acoustically active region. At block 142, the piezoelectric layer can be formed by (1) depositing the piezoelectric layer such that the piezoelectric layer has a different structure in an engineered region than in the main acoustically active region and/or (2) modifying a piezoelectric layer in an engineered region. More details regarding depositing the piezoelectric layer with different structures in different region will be provided with reference to FIGS. 15 to 16C. More details regarding modifying the piezoelectric layer will be provided with reference to FIGS. 17 to 18C.

The method 140 includes depositing a second electrode over the piezoelectric layer at block 144. After the second electrode is formed, the piezoelectric layer is positioned between the first electrode and the second electrode in the main acoustically active region. The piezoelectric layer can be positioned between the first electrode and the second electrode in the frame region in a BAW device after manufacture of the BAW device is complete. The method 140 can include forming one or more other layers and/or structures of one or more of the BAW devices disclosed herein. In some instances, the method 140 can include electrically connecting the BAW device with another BAW device of an acoustic wave filter.

FIG. 15 is a flow diagram of a method 150 of manufacturing a BAW device that involves forming a piezoelectric layer having different structures in different regions according to an embodiment. The method 150 can be performed to form a variety of BAW devices with an engineered piezoelectric layer in accordance with any suitable principles and advantages disclosed herein. The method 150 will be discussed with reference to BAW device structures of FIGS. 16A, 16B, and 16C.

A BAW structure can be provided with different materials exposed in different regions of the BAW structure. Referring to FIG. 16A, the seed layer 33 can be present in a peripheral region of the BAW structure. The seed layer 33 can be formed by atomic layer deposition (ALD), pulsed layer deposition (PLD), molecular beam epitaxy (MBE), sputtering, or any other suitable thin film deposition method. As one example, the seed layer 33 can be an AlN layer formed by any of these processes. The first electrode 22 can be free from the see layer 33 in the central region of the BAW structure over the acoustic reflector 28.

A piezoelectric layer can be formed over different materials in different regions of a BAW device structure at block 152. This can involve depositing the piezoelectric layer directly over a seed layer in a peripheral region of a BAW device and directly over a different layer, such as a lower electrode, in a main acoustically active region of the BAW device. For example, as shown in FIG. 16B, the piezoelectric layer 12 is formed directly over the seed layer 33 in a peripheral region of the BAW structure. This can create the engineered region 12a of the piezoelectric layer 12. The seed layer 33 can have relatively poor crystallinity, have relatively high surface roughness, or can be crystalline with a relatively poor lattice match to the piezoelectric layer 12. Accordingly, the piezoelectric layer 12 over the seed layer 33 can have relatively poor bulk piezoelectric properties. The poor bulk piezoelectric response in the engineered region 12a can be due to one or more of a lack of a preferred orientation of the c-axis in the engineered region 12a, random grain orientation in the engineered region 12a, nearly equal volumes of c-axis oriented regions of opposite polarity in the engineered region 12a, or a defect laden structure containing features such as dislocations and/or stacking faults that decrease the piezoelectric response in the engineered region. In contrast, the piezoelectric layer 12 can have desirable bulk piezoelectric properties in the main piezoelectric region 12b.

Example materials of the seed layer 33 can include, but are not limited to, one or more of aluminum oxide, silicon, silicon carbide, doped aluminum nitride, undoped aluminum nitride, fused silica, boron nitride, diamond, silicon oxycarbide glass, silicon oxynitride glass, boron carbide, graphene, beryllium oxide, gallium nitride, indium nitride, silicon nitride, or scandium nitride. As one example, the seed layer 33 can be silicon dioxide and the piezoelectric layer 12 can be aluminum nitride layer doped with scandium. As another example, the seed layer 33 can be an aluminum nitride seed layer and the piezoelectric layer 12 can be an aluminum nitride layer doped with scandium.

The seed layer 33 can be over the first electrode 22 in the peripheral region and the main acoustically active region can be free from the seed layer 33. The first electrode 22 can include a metal, such as but not limited to Mo, W, Ru, Au, Cu, Ag, Al, Pt, Ir, Cr, Re, Ta, Ni, Pd, Rh, Nb, Ti, Zr, Hf, Be, V, Mn, Fe, Co, Ni, Zn, Os, metallic carbides such as WC, metallic nitrides such as TiN, other metals, alloys containing two or more of these metals, multi-phase mixtures of such alloys or metals, or multiple layer stacks including these metals, alloys or multi-phase mixtures. In some applications, a seed layer can be deposited on a temperature compensating material, such as fused silica positioned between a lower electrode and the seed layer for a temperature compensated BAW (TCBAW) device, or a semiconducting material, such as Si, Ge, GaN or GaAs.

Depositing the piezoelectric layer 12 over the seed layer 33 can rotate and/or tilt the orientation in the engineered region 12a. For example, the seed layer 33 can be aluminum or aluminum oxide and depositing an aluminum nitride piezoelectric layer over such a seed layer 33 can adjust the orientation of the c-axis. Other methods of tiling the c-axis of the piezoelectric layer in the engineered region 12a can include, but are not limited to, surface reduction of the first electrode 22 with H₂ gas in the peripheral region before piezoelectric layer deposition, surface oxidation of the first electrode 22 in the peripheral region before piezoelectric layer deposition, oxygen doping in the peripheral region during piezoelectric layer deposition, forming a Si or Ge doped AlN seed layer on the first electrode 22 in the engineered region, or inducing bias power (voltage) in sputtering plasma.

The c-axis of the piezoelectric layer 12 in the peripheral region can be rotated such that the c-axis is oriented at an angle in a range from 90° to 150° in the peripheral region to relative to a c-axis of the piezoelectric layer 12 in the main acoustically active region. In some such instances, the c-axis in the peripheral region can be oriented at an angle of 120° in the peripheral region relative to the c-axis in the main acoustically active region.

Referring to FIG. 15, a second electrode can be deposited over the piezoelectric layer at block 154. As shown in FIG. 16C, after the second electrode 24 is formed, the piezoelectric layer 12 is positioned between the first electrode 22 and the second electrode 24 in the main acoustically active region. The method 150 can include forming one or more other layers and/or structures of one or more of the BAW devices disclosed herein. For example, a raised frame structure and/or a recessed frame structure can be formed in the peripheral region. Forming at least part the raised frame structure and/or at least part of the recessed frame structure can be performed after depositing the second electrode 24 at block 154 in certain applications. In some applications, at least part of one or more frame structures can be formed prior to depositing the second electrode 24 at block 154. In some instances, part of a raised frame structure can be formed prior depositing the second electrode 24 and part of the raised frame structure can be formed after depositing the second electrode 24. The engineered region 12a of the piezoelectric layer 12 can be positioned between the first electrode 22 and the second electrode 24 in a frame region of a BAW device after manufacture of the BAW device is complete. In some instances, the method 150 can include electrically connecting the BAW device with another BAW device of an acoustic wave filter.

In other some applications, a seed layer can be included over the lower electrode in a main acoustically active region to promote growth of the piezoelectric layer directly over the seed layer and the peripheral region can be free from this seed layer. The lack of this seed layer in the peripheral region can contribute to the piezoelectric layer formed in the peripheral region having less desirable bulk piezoelectric properties compared to the piezoelectric layer in the main acoustically active region.

In some other applications, a seed layer below the first electrode can be included in the main acoustically active region and not in a peripheral region. The lack of this seed layer in the peripheral region can contribute to forming a recessed frame structure. The piezoelectric layer can be deposited over the first electrode with less desirable growth over the peripheral region in such applications to form an engineered region.

In some other applications, a seed layer can be positioned on the passivation layer 32 in the peripheral region to deteriorate crystallinity of the first electrode 22 formed thereover, which can make a relatively poor crystalline piezoelectric layer 12 in the engineered region 12a. The main acoustically active region of the BAW device can be free from this seed layer. Such a seed layer can be formed by any suitable process disclosed herein.

FIG. 17 is a flow diagram of a method 170 of manufacturing a BAW device that involves modifying a piezoelectric layer in a peripheral region of the BAW device. The method 170 can be performed to form a variety of BAW devices with an engineered piezoelectric layer in accordance with any suitable principles and advantages disclosed herein. The method 170 will be discussed with reference to BAW device structures of FIGS. 18A, 18B, and 18C.

A piezoelectric layer can be applied over a first electrode at block 172. FIG. 18A illustrates a BAW device structure after the piezoelectric layer 12 is applied. The piezoelectric layer 12 can have a generally uniform structure in the BAW device structure shown in FIG. 18A. The piezoelectric layer 12 can have generally uniform piezoelectric properties immediately after applying the piezoelectric layer 12 at block 172. The piezoelectric layer 12 can be formed by any suitable deposition method. For example, the piezoelectric layer 12 can be formed by sputtering. The piezoelectric layer 12 can be an aluminum nitride piezoelectric layer. The piezoelectric layer 12 can be doped. For example, the piezoelectric layer 12 can be an aluminum nitride layer doped with scandium.

Referring to FIG. 17, the piezoelectric layer can be modified in a peripheral region at block 174. This can engineer the piezoelectric layer to have one or more different properties in the peripheral region of the BAW device than in the main acoustically active region of the BAW device. Modifying the piezoelectric layer in the peripheral region can involve modifying a structure of the piezoelectric layer in the peripheral region. This can induce amorphization and/or reduce a degree of crystallinity in the peripheral region relative to in the main acoustically active region.

FIG. 18B illustrates a BAW device structure after the piezoelectric layer 12 is modified in the peripheral region at block 174. The BAW device structure of FIG. 18B includes a piezoelectric layer 12 with an engineered region 12a and a main piezoelectric region 12b. The engineered region 12a has a different physical structure than the main piezoelectric region 12b as a result of the modification at block 174.

Modifying the piezoelectric layer 12 can involve ion implantation. In some applications, modifying the piezoelectric layer 12 can involve applying laser light to disrupt the crystal structure and piezoelectricity of the piezoelectric layer in the peripheral region. Modifying the piezoelectric layer 12 can involve any other suitable way of modifying the piezoelectric layer for engineering properties of the piezoelectric layer in the peripheral region.

Ion implantation can be employed to modify the structure and/or composition of the piezoelectric layer 12 in the engineered region 12a at block 174. Ion implantation is a relatively low-temperature technique for the introduction of impurities (e.g., dopants). Ion implantation can be performed at block 174 after the piezoelectric layer is deposited at block 172. In ion implantation, dopant atoms can be volatilized, ionized, accelerated, separated by the mass-to-charge ratios, and directed at the piezoelectric layer 12 in a peripheral region. The accelerated ions can have precise energy and high purity. The ions can enter the crystal lattice of the piezoelectric layer 12, collide with the host atoms, lose energy, and finally come to rest at some depth within the piezoelectric layer 12.

When ions penetrate the piezoelectric layer 12, the ions can undergo a series of collisions that result in displacement of the target atoms, which in turn can result in the formation of point defects. When relatively heavy ions are implanted at a sufficiently high dose, the degree of crystallinity of the piezoelectric layer 12 can be substantially reduced due to a relatively high degree of displacement of target atoms. When the implanted ions are inert elements, substantial physical amorphization of the piezoelectric layer 12 can be achieved without affecting the base chemical composition of the piezoelectric layer 12. Accordingly, ion implantation can reduce a crystallinity of the piezoelectric layer 12 in the engineered region 12a. This can involve using ions of chemically inert elements, for example, a noble gas (e.g., He, Kr, Ar, Ne, Xe) or N₂. Ion implantation can disrupt piezoelectric layer crystallinity with physical force. Accordingly, noble and/or heavy elements can be used as ions for implantation in certain applications. Any suitable ions can be used for a particular application. Some example ions include boron, phosphorus, and arsenic.

After ion implantation, an implanted species can be included in the engineered region 12a of the piezoelectric layer 12. The main piezoelectric region 12b of the piezoelectric layer 12 can be free from the implanted species after ion implantation. Alternatively or additionally, a different ion implanted dose can be included in the engineered region 12a of the piezoelectric layer 12 than in the main piezoelectric region 12b of the piezoelectric layer 12 after ion implantation.

As shown in FIG. 18C, the second electrode 24 can be deposited over the piezoelectric layer 12. Manufacturing a BAW device can include forming one or more other layers and/or structures of one or more of the BAW devices disclosed herein. For example, a raised frame structure and/or a recessed frame structure can be formed in the peripheral region. Forming at least part of a raised frame structure and/or at least part of a recessed frame structure can be performed after depositing the second electrode 24 in certain applications. In some applications, at least part of one or more frame structures can be formed prior to depositing the second electrode 24. In some instances, part of a raised frame structure can be formed prior depositing the second electrode 24 and part of the raised frame structure can be formed after depositing the second electrode 24. The piezoelectric layer 12 can be positioned between the first electrode 22 and the second electrode 24 in a frame region of a BAW device after manufacturing is complete. A BAW device can be connected to another BAW device of an acoustic wave filter during manufacturing.

Performance Parameters of BAW Devices with Engineered Piezoelectric Layer

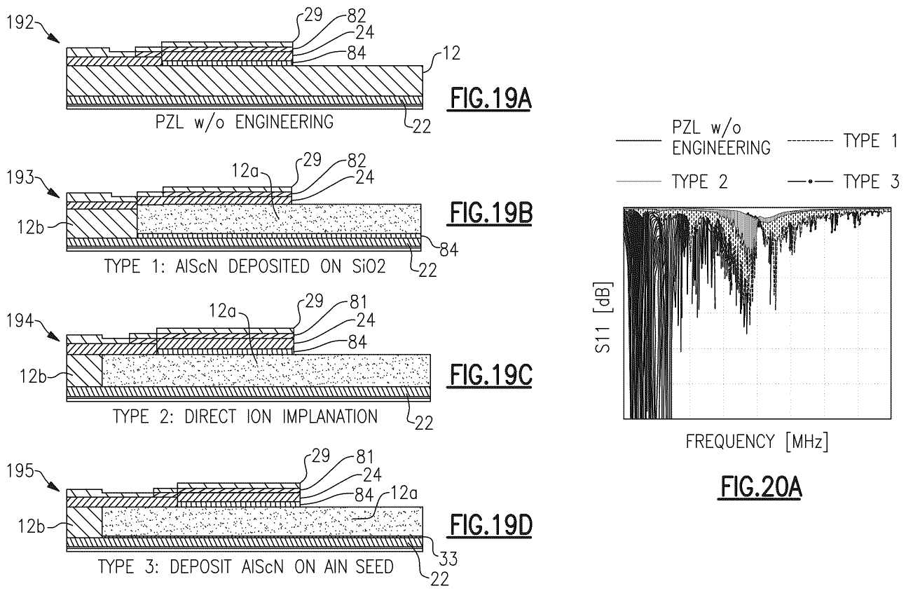

BAW devices manufactured by various methods disclosed herein can achieved desirable performance parameters. Graphs representing frequency response, Qp, and spur intensity of BAW devices manufacture by methods disclosed herein compared to BAW devices with a piezoelectric layer without an engineered region disclosed herein will be discussed with reference to FIGS. 19A to 20C.

FIG. 19A illustrates a portion of a BAW device 192 that includes a piezoelectric layer 12 without an engineered region. The BAW device 192 includes a recessed frame structure and two raised frame layers 82 and 84.

FIG. 19B illustrates a portion of a BAW device 193 with a piezoelectric layer 12 with an engineered region 12a according to an embodiment. The BAW device 193 includes a raised frame layer 84 under the piezoelectric layer 12 in the engineered region 12a. The engineered region 12a overlaps the raised frame layers 82 and 84 in the BAW device 193. In the BAW device 193, the raised frame layer 84 is a silicon dioxide layer and the piezoelectric layer 12 is an aluminum nitride layer doped with scandium.

FIG. 19C illustrates a portion of a BAW device 194 with a piezoelectric layer 12 with an engineered region 12a according to an embodiment. In the BAW device 194, the piezoelectric layer 12 is in physical contact with the first electrode 22 in the engineered region 12a. The engineered region 12a in the piezoelectric layer 12 of the BAW device 194 is formed by direct ion implantation. The engineered region 12a includes ions implanted therein. The engineered region 12a overlaps with the raised frame layers 82 and 84 and the recessed frame structure in the BAW device 194.

FIG. 19D illustrates a portion of a BAW device 195 with a piezoelectric layer 12 with an engineered region 12a according to an embodiment. The BAW device 195 includes a seed layer 33 under the piezoelectric layer 12 in the engineered region 12a. The engineered region 12a overlaps the raised frame layers 82 and 84 and the recessed frame structure in the BAW device 195. In the BAW device 195, the seed layer 33 is an aluminum nitride seed layer and the piezoelectric layer 12 is an aluminum nitride layer doped with scandium.

FIG. 20A is a graph with frequency responses of the BAW devices of FIGS. 19A to 19D. FIG. 20A indicates that the BAW devices 193, 194, and 195 have improved frequency responses relative to the BAW device 192.

FIG. 20B is a plot of Qp distributions for the BAW devices of FIGS. 19A to 19D. FIG. 20B indicates that the BAW devices 194 and 195 have significantly increased Qp performance relative to the BAW device 192. FIG. 20B also indicates that the BAW devices 194 and 195 have increased Qp relative to the BAW device 193. This can be at least partly due to the engineered region 12a being in the recessed frame region in the BAW devices 194 and 195 and not being in the recessed frame region in the BAW device 193.

FIG. 20C is a plot of spur intensity distributions for the BAW devices of FIGS. 19A to 19D. FIG. 20C indicates that the BAW devices 193, 194 and 195 have significantly decreased spur intensity relative to the BAW device 192.

FIG. 21A is cross-sectional schematic diagram of a BAW device 196. FIG. 21B is a graph of Qp for various width combinations of raised frame layers of the BAW device 196. These raised frame layers include a metal raised frame layer with a width MraW and an oxide raised frame layer with a width ORaW. FIG. 21C is a graph of spur intensity for various width combinations of raised frame layers of the BAW device 196.

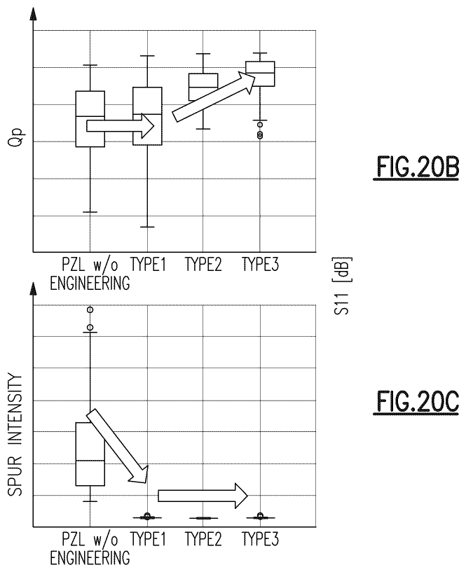

FIG. 22A is cross-sectional schematic diagram of a BAW device 197. The BAW device 197 is like the BAW device 196, expect that the BAW device 197 includes a piezoelectric layer 12 with an engineered region 12a. FIG. 22B is a graph of Qp for various width combinations of raised frame layers of the BAW device 197. These raised frame layers include a metal raised frame layer with a width MraW and an oxide raised frame layer with a width ORaW. FIG. 22B indicates that BAW device 197 generally has higher Qp than the BAW device 196. FIG. 22C is a graph of spur intensity for various width combinations of raised frame layers of the BAW device 197. FIG. 22C indicates that BAW device 197 has significantly lower spur intensity than the BAW device 196.

Accordingly, an engineering a region of the piezoelectric layer in accordance with any suitable principles and advantages disclosed herein can increase the Qp and reduce frame mode intensity while maintaining the kt² at generally the same level. The kt² can be adjusted by varying a percentage of a dopant in the piezoelectric layer regardless of dimensions of a frame structure when the piezoelectric layer has an engineered region in accordance with any suitable principles and advantages disclosed herein. For example, varying a scandium percentage in an aluminum nitride piezoelectric layer can adjust the kt².

The engineered region can be in a frame region of a BAW device. The engineered region can extend from the frame region toward the main acoustically active region of the BAW device. Such BAW devices can achieve higher and more uniform Qp than certain state of the art BAW devices. At the same time, the kt² of the BAW devices can be relatively stable. There can be no significant frame modes below fd. Generally the same level of lateral mode intensity can be present between fd and fs in BAW devices of embodiments disclosed herein. Suppression of such lateral modes can depend on raised frame structure.

BAW Devices with Single Raised Frame Layer and Engineered Piezoelectric Layer

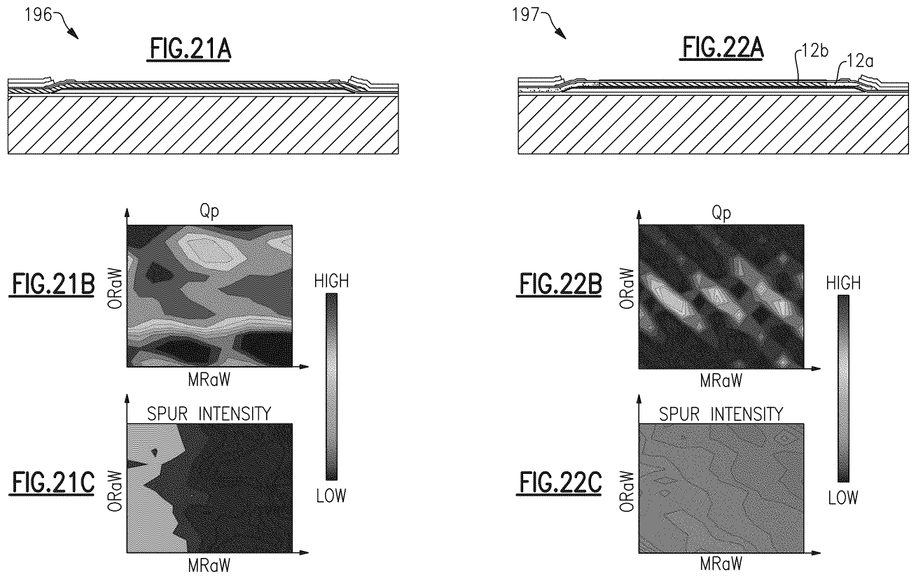

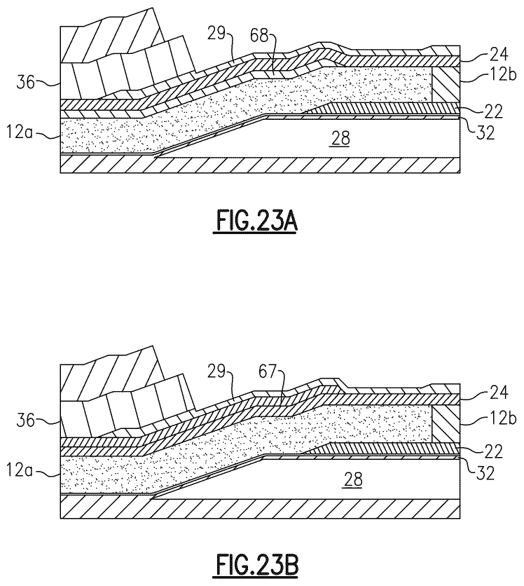

BAW devices with a variety of frame structures are disclosed herein. In certain applications, a single raised frame structure can be included in a BAW device that includes a piezoelectric layer with an engineered region. For example, a single oxide raised frame layer, a single metal raised frame layer, or a single piezoelectric raised frame layer can be included in a BAW device with an engineered region of a piezoelectric layer in a frame region of the BAW device. Example BAW devices with a single raised frame layer are discussed with reference to FIGS. 23A, 23B, and 23C. A thickness of the single raised frame layer in these BAW devices can have a relatively small impact on performance parameters of the BAW devices. A BAW device with a single raised frame layer can be manufactured with fewer manufacturing steps and/or less complexity compared to multilayer raised frame structures.

FIG. 23A is cross-sectional schematic diagram of a part of BAW device that includes an oxide raised frame layer 68 and a piezoelectric layer 12 with an engineered region 12a according to an embodiment. A metal top electrode connection side of a BAW device is shown in FIG. 23A where the second electrode 24 connects to conductive layer 36. A raised frame structure of the BAW device of FIG. 23A can consist or consist essentially of the oxide raised frame layer 68. Accordingly, the BAW device of FIG. 23A can include one type of raised frame (i.e., an oxide raised frame). In certain embodiments, a frame structure of the BAW device can consist or consist essentially of an oxide raised frame layer 68. The BAW device of FIG. 23A is similar to the BAW device 60 of FIGS. 6A to 6C, except that the BAW device of FIG. 23A does not include a metal raised frame layer. A raised frame structure consisting of or consisting essentially of one oxide raised frame layer 68 can be implemented in BAW devices with a recessed frame structure in certain applications. A raised frame structure consisting of or consisting essentially of one oxide raised frame layer 68 can be implemented in BAW devices without a recessed frame structure in some other applications. With the oxide raised frame layer 68 and the engineered region 12a of the piezoelectric layer, the BAW device of FIG. 23A can have a relatively high Q while having little or no raised frame mode.

FIG. 23B is cross-sectional schematic diagram of a part of BAW device that includes a metal raised frame layer 67 and a piezoelectric layer with an engineered region 12a according to an embodiment. A metal top electrode connection side of a BAW device is shown in FIG. 23B where the second electrode 24 connects to conductive layer 36. A raised frame structure of the BAW device of FIG. 23B can consist or consist essentially of the metal raised frame layer 67. Accordingly, the BAW device of FIG. 23B can include one type of raised frame (i.e., a metal raised frame). In certain embodiments, a frame structure of the BAW device can consist or consist essentially of a metal raised frame layer 67. The BAW device of FIG. 23B is similar to the BAW device 60 of FIGS. 6A to 6C, except that the BAW device of FIG. 23B does not include an oxide raised frame layer. A single metal raised frame layer 67 can be implemented in BAW devices with a recessed frame structure in certain applications. A single metal raised frame layer 67 can be implemented in BAW devices without a recessed frame structure in some other applications. The illustrated metal raised frame layer 67 can be formed with a dry etch. This can create an approximately 45° angle for the metal raised frame layer 67. With the metal raised frame layer 67 and the engineered region 12a of the piezoelectric layer, the BAW device of FIG. 23B can have a relatively high Q while having little or no raised frame mode.

FIG. 23C is cross-sectional schematic diagram of a part of BAW device that includes a piezoelectric raised frame layer 12c and a piezoelectric layer with an engineered region 12b according to an embodiment. A metal top electrode connection side of a BAW device is shown in FIG. 23C where the second electrode 24 connects to conductive layer 36. A raised frame structure of the BAW device of FIG. 23C can consist or consist essentially of the piezoelectric frame layer 12c. Accordingly, the BAW device of FIG. 23C can include one type of raised frame (i.e., a piezoelectric raised frame). In certain embodiments, a frame structure of the BAW device can consist or consist essentially of a piezoelectric frame layer 12c. The piezoelectric raised frame layer 12c can be implemented in a BAW device with a recessed frame structure or in a BAW device without a recessed frame structure. The piezoelectric raised frame layer 12c has a thickness PRaF. This thickness can be sufficient to provide a difference in mass loading to reduce lateral energy leakage from the main acoustically active region. The piezoelectric raised frame layer 12c can include engineered piezoelectric material such that the piezoelectric raised frame layer 12c is like the engineered region 12a of the piezoelectric layer. The piezoelectric raised frame layer 12c can be engineered in the same way and have the same properties as the engineered region 12a of the piezoelectric layer 12 in certain applications.

Frameless BAW Devices with Engineered Piezoelectric Layer

Certain BAW devices can include a piezoelectric layer with an engineered region and be free from a frame structure. Such a BAW devices can be referred to as frameless BAW devices with an engineered piezoelectric layer. Simulation results indicate that a frameless BAW device that includes a piezoelectric layer with an engineered region aligned with an edge of the active region can achieve a desirable Qp. This desirable Qp may be lower than a maximum Qp of a similar device that additionally includes a frame structure. Frameless BAW devices can have a resonant frequency of at least 2.5 GHz in certain applications. The resonant frequency in some such applications can be in a range from 2.5 GHz to 7 GHz. A frameless BAW device can be used for ultra-high band (UHB) resonators with a relatively smaller area to overcome technical challenges associated without such UHB resonators. UHB resonators can have a resonant frequency in a range from 3 GHz to 7 GHZ, such as in a range from 3 GHz to 6 GHz or in a range from 3.3 GHz to 5 GHz.

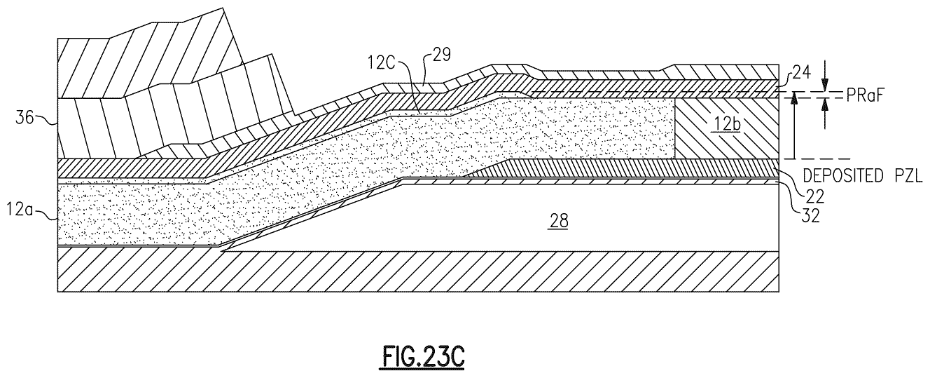

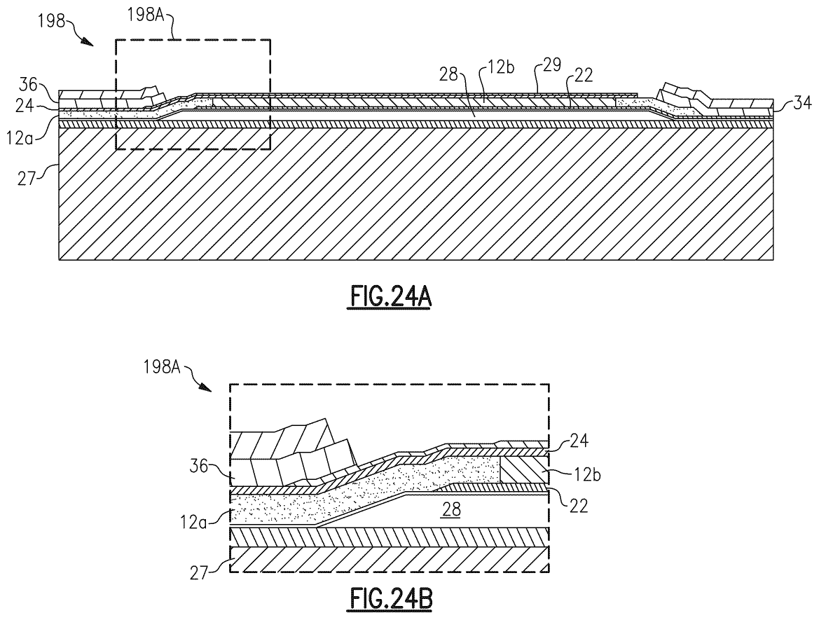

FIG. 24A is cross-sectional schematic diagram of a frameless BAW device 198 that includes a piezoelectric layer 12 with an engineered region 12a according to an embodiment. FIG. 24B is a zoomed in view of part 198A of the frameless BAW device 198 of FIG. 24A. The frameless BAW device 198 does not include a frame structure over the piezoelectric layer 12. In the frameless BAW device 198, the engineered region 12a of the piezoelectric layer 12 is aligned with an edge of the active region of the frameless BAW device 198. Such alignment can contribute to achieving a desirable Qp for the frameless BAW device 198. If an edge of the engineered region 12a closest to the center of the frameless BAW device 198 were moved farther from the center than shown in FIG. 24A, simulations indicate that Qp would decrease. Simulations indicate that moving an edge of the engineered region 12a closest to the center of the frameless BAW device 198 closer to the center of the frameless BAW device 198 than shown in FIG. 24A can increase Qp in certain applications. In the frameless BAW device 198, the engineered region 12a of the piezoelectric layer 12 extends beyond the air cavity 28. This illustrates that in frameless BAW devices an engineered region 12a of a piezoelectric layer 12 can (1) overlap with a frame structure over an acoustic reflector and (2) extend beyond the acoustic reflector. In the frameless BAW device 198, the air cavity 28 is over the support substrate 27. A surface of the support substrate 27 is planar under the entirety of the first electrode 22 and the second electrode 24.

Frameless BAW devices can include a piezoelectric layer with an engineered region in accordance with any suitable principles and advantages disclosed herein. Such frameless BAW devices can be used for UHB BAW resonators. In certain applications, a temperature compensation layer (e.g., similar to the temperature compensation layer 99 of FIGS. 25A and 25B) can be included in a frameless BAW device that includes a piezoelectric layer with an engineered region.

Temperature Compensated BAW Devices with Engineered Piezoelectric Layer

Certain BAW devices can include a temperature compensation layer that brings a temperature coefficient of frequency (TCF) closer to zero. Such BAW devices can be referred to as temperature compensated BAW (TC BAW) devices. Any suitable principles and advantages of engineering a piezoelectric layer disclosed herein can be applied to TC BAW devices. An example TC BAW device will be discussed with reference to FIGS. 25A and 25B.

FIG. 25A is cross-sectional schematic diagram of a temperature compensated BAW device 199 that includes a piezoelectric layer 12 with an engineered region 12a according to an embodiment. FIG. 25B is a zoomed in view of part of the temperature compensated BAW device 199 of FIG. 25A. The BAW device 199 is a TC BAW device. The temperature compensation layer 99 can compensate for temperature shift. With the engineered region 12a of the piezoelectric layer 12, thickness extension modes can be attenuated and/or completely removed and a high Qp can be achieved. A raised frame mode can be suppressed by the engineered region 12a of the piezoelectric layer 12 in the BAW device 199. Simulation results indicate that TC BAW devices with the engineered region 12a of the piezoelectric layer 12 can achieve desirable frame mode suppression and high Qp values.

The BAW device 199 includes a temperature compensation layer 99 to bring the TCF of the BAW device 199 closer to zero relative to a similar BAW device without the temperature compensation layer 99. The temperature compensation layer 99 can have a positive TCF. This can compensate for the piezoelectric layer 12 having a negative TCF. The temperature compensation layer 99 can be a silicon dioxide (SiO₂) layer. The temperature compensation layer 99 can be any other suitable temperature compensation layer, such as but not limited to a layer of one or more of aluminum oxide, silicon carbide, silicon nitride, silicon oxynitride, tellurium dioxide, silicon oxyfluoride, or the like. The temperature compensation layer 99 can include a dielectric material.

The temperature compensation layer 99 can be in the acoustically active region and the peripheral region of the BAW device 99. The temperature compensation layer 99 can be positioned between the first electrode 22 and the second electrode 24. The temperature compensation layer 99 can be positioned between a surface of the first electrode 22 and a surface of the second electrode 24. As illustrated in FIGS. 25A and 25B, the temperature compensation layer 99 is positioned between an electrode of the BAW device 199 (e.g., the second electrode 24 in FIGS. 25A and 25B) and the piezoelectric layer 12. The temperature compensation layer 99 can be in physical contact with the piezoelectric layer 12. The temperature compensation layer 99 can be in physical contact with an electrode of the BAW device (e.g., the second electrode 24 in FIGS. 25A and 25B).

TC BAW devices can include a temperature compensation layer (1) between a piezoelectric layer and upper electrode (e.g., as illustrated in FIGS. 25A and 25B), (2) between the piezoelectric layer and lower electrode, (3) embedded within a piezoelectric layer, (4) embedded within an electrode, or (5) any suitable combination of (1) to (4). Any such TC BAW devices can include a piezoelectric layer with an engineered region in accordance with any suitable principles and advantages disclosed herein.

Applications for BAW Device with Engineered Piezoelectric Layer

BAW devices disclosed herein can be implemented in a variety of applications. Applications of these BAW devices include, but are not limited to, a BAW resonator for filter that filters an electrical signal, a BAW oscillator such as a BAW oscillator for a clock generator, a BAW sensor (e.g., a gas sensor, a particle sensor, a mass sensor, a pressure or touch sensor, etc.), a BAW delay line such as BAW delay line for radar and/or instrumentation applications, an actuator, a microphone, and a speaker. Filters that include BAW resonators can be implemented in a variety of applications including, but not limited to, mobile phones, base stations, repeaters, relays, wireless communication infrastructure, access points, customer premises equipment (CPE), and distributed antenna systems. BAW oscillators can replace crystal oscillators in a variety of applications, such as but not limited to electronic timing products.

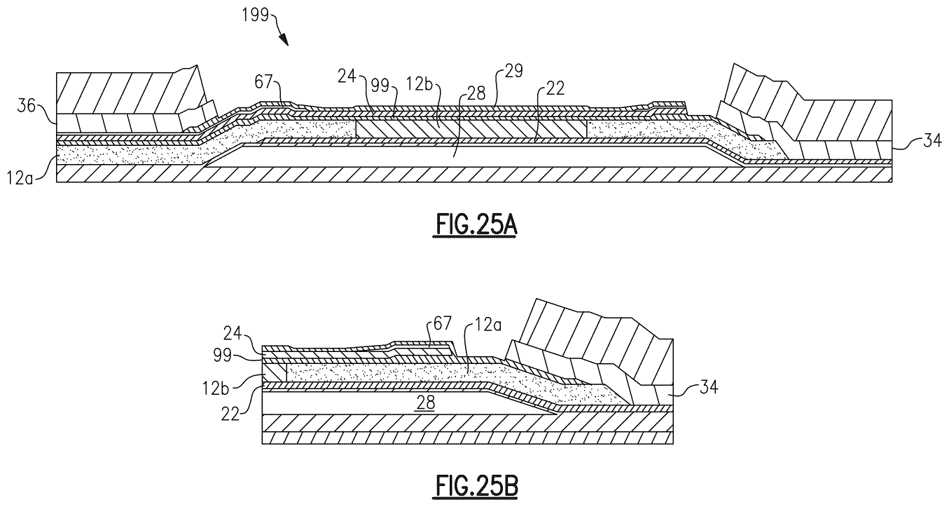

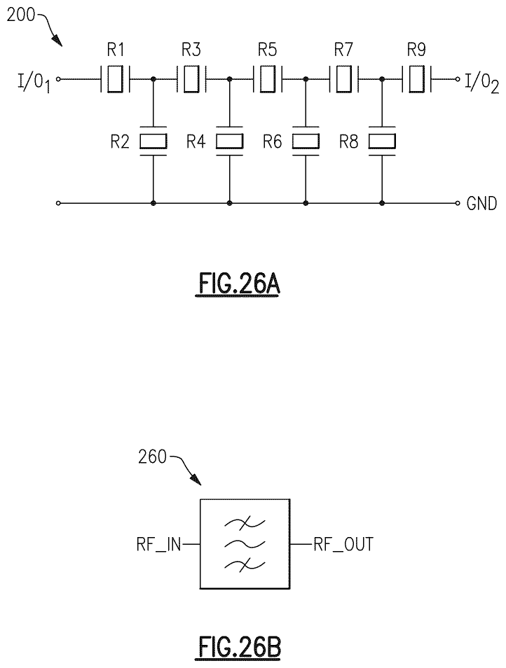

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 26A.

FIG. 26A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, first input/output port I/O₁ can be a receive port and the second input/output port I/O₂ can be an antenna port. One or more of the acoustic wave resonators of the ladder filter 200 can include a BAW resonator including a piezoelectric layer with an engineered region in accordance with any suitable principles and advantages disclosed herein. All acoustic resonators of the ladder filter 200 can include a BAW resonator including a piezoelectric layer with an engineered region in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band.

The BAW resonators disclosed herein can be advantageous for implementing BAW devices with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 26B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

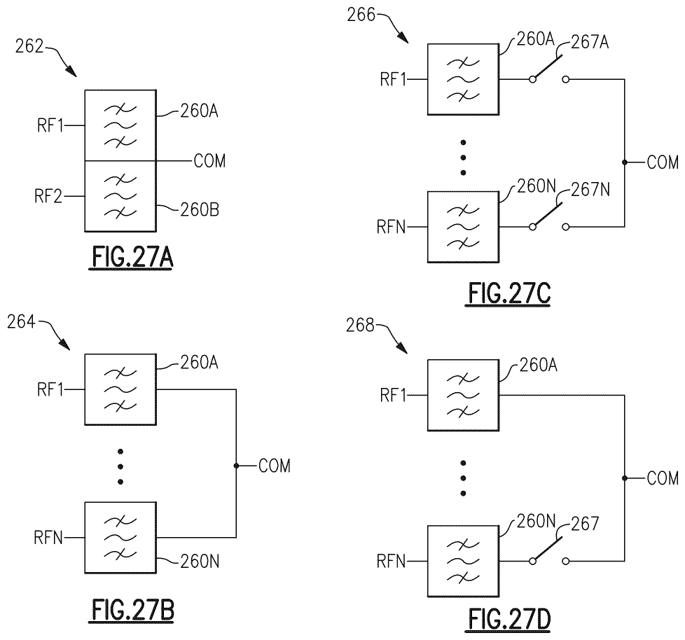

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 27A to 27D. Any suitable principles and advantages of these multiplexers can be implemented together with each other.

FIG. 27A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 27B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 27C is a schematic diagram of a multiplexer 266 that includes an acoustic wave filter according to an embodiment. The multiplexer 266 is like the multiplexer 264 of FIG. 27B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 27D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

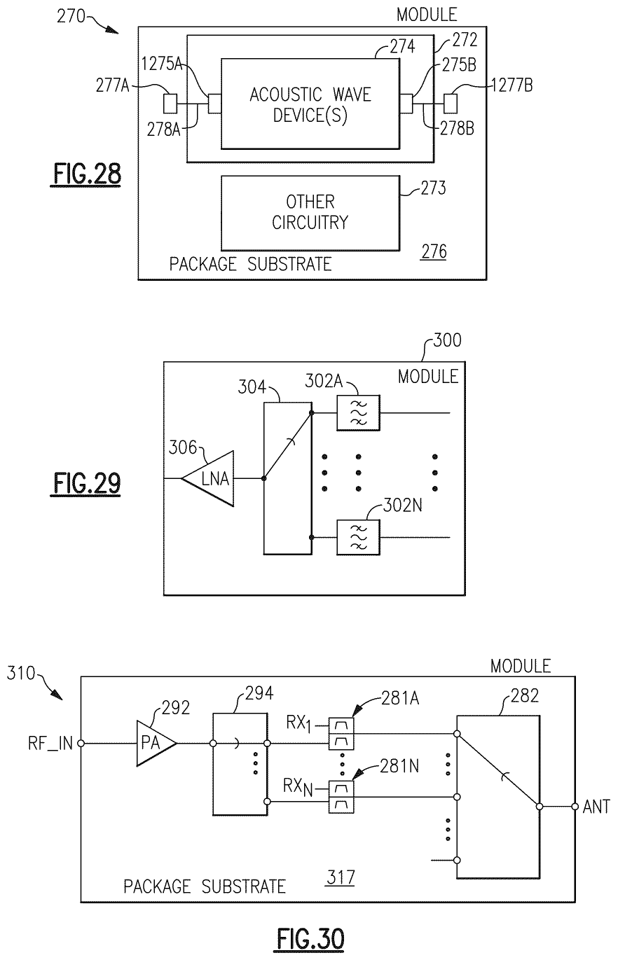

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 28, 29, and 30 are schematic block diagrams of illustrative packaged modules according to certain embodiments. Any suitable combination of features of these packaged modules can be implemented with each other.

FIG. 28 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 28 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 28. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 29 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

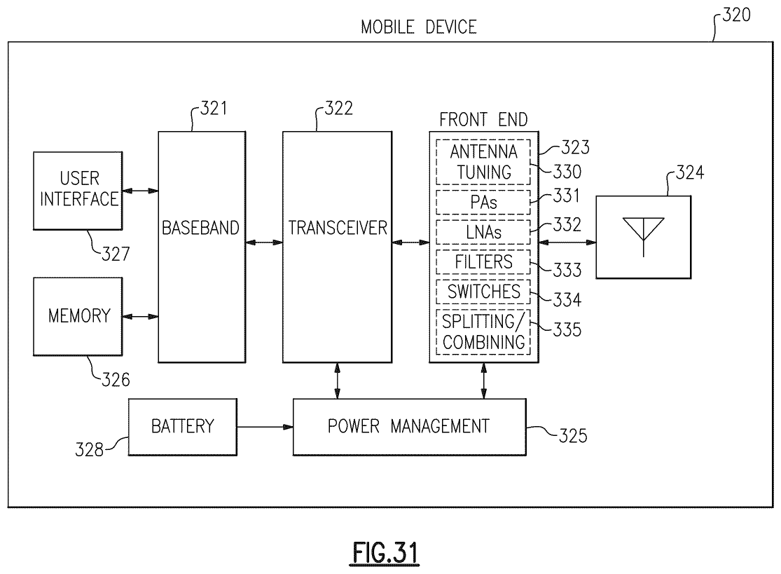

FIG. 30 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 30 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 30 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

The BAW devices disclosed herein can be implemented in wireless communication devices. FIG. 31 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 31 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAS) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 31, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 31, the power management system 325 receives a battery voltage from the battery 328. The battery 328 can be any suitable battery for use in the wireless communication device 320, including, for example, a lithium-ion battery.

### TERMINOLOGY AND CONCLUSION

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHZ, in FR1, in a frequency range from about 2 GHz to 10 GHz, in a frequency range from about 2 GHz to 15 GHZ, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device having a main acoustically active region and a raised frame region, the bulk acoustic wave device comprising:
a first electrode;
a second electrode;
a raised frame structure in the raised frame region, the raised frame structure positioned around the main acoustically active region; and
a piezoelectric layer positioned between the first electrode and the second electrode in at least the main acoustically active region, the piezoelectric layer being engineered in the raised frame region such that the piezoelectric layer has a greater magnitude effective piezoelectric coefficient in the main acoustically active region than in the raised frame region.

2. The bulk acoustic wave device of claim 1 wherein the piezoelectric layer has deteriorated crystallinity in the raised frame region relative to in the main acoustically active region.

3. The bulk acoustic wave device of claim 1 wherein the piezoelectric layer is amorphous in the raised frame region.

4. The bulk acoustic wave device of claim 1 wherein the effective piezoelectric coefficient is an effective piezoelectric coupling coefficient (e₃₃), and a magnitude of the effective piezoelectric coefficient is no more than 50% in the raised frame region of the magnitude of the effective piezoelectric coefficient in the main acoustically active region.

5. The bulk acoustic wave device of claim 1 wherein the effective piezoelectric coefficient is an effective piezoelectric coupling coefficient (e₃₃), and a magnitude of the effective piezoelectric coefficient is no more than 20% in the raised frame region of the magnitude of the effective piezoelectric coefficient in the main acoustically active region.

6. The bulk acoustic wave device of claim 1 further comprising a seed layer positioned between the first electrode and the piezoelectric layer in the raised frame region, the main acoustically active region being free from the seed layer.

7. The bulk acoustic wave device of claim 6 wherein the seed layer includes at least one of an oxide, a nitride, a carbide, or a boride material.

8. The bulk acoustic wave device of claim 6 wherein the seed layer includes a metal base.

9. The bulk acoustic wave device of claim 1 wherein the piezoelectric layer includes ions implanted therein in the raised frame region.

10. The bulk acoustic wave device of claim 1 wherein the piezoelectric layer is engineered in an intermediate region of the bulk acoustic wave device that is between the raised frame region and the main acoustically active region.

11. The bulk acoustic wave device of claim 1 further comprising a recessed frame structure in a recessed frame region, the recessed frame region being between the main acoustically active region and the raised frame region, and the piezoelectric layer being engineered in at least part of the recessed frame region.

12. The bulk acoustic wave device of claim 1 wherein the raised frame region includes a first raised frame region and a second raised frame region, and the raised frame structure includes an additional raised frame layer in the second raised frame region relative to in the first raised frame region.

13. The bulk acoustic wave device of claim 1 wherein the raised frame structure includes an oxide raised frame layer and a metal raised frame layer.

14. The bulk acoustic wave device of claim 1 further comprising an air cavity, the piezoelectric layer being over the air cavity in the raised frame region and the main acoustically active region.

15. The bulk acoustic wave device of claim 1 wherein the piezoelectric layer includes aluminum nitride doped with scandium.

16. The bulk acoustic wave device of claim 1 wherein the raised frame structure surrounds the main acoustically active region.

17. A bulk acoustic wave device having a main acoustically active region a peripheral region surrounding the main acoustically active region, the bulk acoustic wave device comprising:
a first electrode;
a second electrode;
a frame structure at least partly in the peripheral region; and
a piezoelectric layer positioned between the first electrode and the second electrode in at least the main acoustically active region, the piezoelectric layer being engineered in the peripheral region such that the piezoelectric layer has a greater magnitude effective piezoelectric coefficient in the main acoustically active region than in the peripheral region.

18. The bulk acoustic wave device of claim 17 wherein the frame structure is fully within the peripheral region, and the peripheral region extends beyond the frame structure toward the main acoustically active region.

19. The bulk acoustic wave device of claim 17 further comprising a seed layer positioned between the first electrode and the piezoelectric layer in the peripheral region.

20. An acoustic wave filter for filtering a radio frequency signal, the acoustic wave filter comprising:
a bulk acoustic wave resonator including a first electrode, a second electrode, a raised frame structure in a raised frame region of the bulk acoustic wave resonator, and a piezoelectric layer positioned between the first electrode and the second electrode in at least a main acoustically active region of the bulk acoustic wave resonator, the piezoelectric layer being engineered in the raised frame region such that the piezoelectric layer has a greater magnitude effective piezoelectric coefficient in the main acoustically active region than in the raised frame region; and
a plurality of additional acoustic wave resonators, the bulk acoustic wave resonator and the plurality of additional acoustic wave resonators configured to filter the radio frequency signal.
